(19) United States
(12) Patent Application Publication
(10) Pub. No.: US 2026/0245596 A1
(43) Pub. Date: Aug. 20, 2026

(54) MEMORY DEVICE INCLUDING SEGMENTED CONDUCTIVE CONTACTS

(71) Applicant: Micron Technology, Inc., Boise, ID (US)

(72) Inventors: Matthew J. King, Boise, ID (US); Sidhartha Gupta, Boise, ID (US); Harsh Narendrakumar Jain, Boise, ID (US); Terry Hyunsik Kim, Boise, ID (US); Tyler List, Boise, ID (US)

(21) Appl. No.: 19/057,749

(22) Filed: Feb. 19, 2025

(51) Int. Cl. G11C 5/06; G11C 16/04; H10B 41/10; H10B 41/30

(52) U.S. Cl. CPC G11C 5/063; G11C 16/0483; H10B 41/10; H10B 41/30

(57) ABSTRACT

Some embodiments include apparatuses and methods of forming the apparatuses. One of the apparatuses includes: levels of dielectric materials interleaved with the levels of conductive materials, the levels of conductive materials including a first level and a second level; a memory cell string including a pillar extending through the levels of conductive materials and the levels of dielectric materials; and a conductive contact extending in a direction from the first level to the second level, the conductive contact contacting the second level of the levels of conductive materials. The conductive contact includes first region having a first width, a second region having a second width, and a third region having a third width. The second region is between the first region and the third region. The second width is greater than each of the first width and the third width.

### BACKGROUND

A memory device (e.g., a flash memory device) has numerous tiers of memory cells and associated control gates. The memory device also has conductive contacts to provide control signals (e.g., word line signals) to the control gates for controlling access to memory cells. The conductive contacts often extend through the tiers and in electrical contact with respective control gates. Dimensions of structures of a memory device are relatively small (e.g., in nanometer size). At a certain dimension, improperly forming conductive contacts in such a memory device can negatively affect at least one of cost, performance, and reliability of the memory device.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3A shows a detailed schematic diagram of two blocks of the memory device of FIG. 2, according to some embodiments described herein.

FIG. 3B shows an example of the memory device of FIG. 3A including multiple drain select gates, according to some embodiments described herein.

FIG. 4 shows a top view of a structure of a portion of the memory device of FIG. 3A including a region of a memory array, a conductive contact region, and structures between the blocks of the memory device, according to some embodiments described herein.

FIG. 5A shows a side view (e.g., cross-section) of a structure of a portion of the memory device of FIG. 4, including tiers of materials that include respective memory cells and control gates associated with the memory cells, according to some embodiments described herein.

FIG. 5B shows a variation of the memory device of FIG. 5A, including a memory cell pillar associated with multiple drain select gates, according to some embodiments described herein.

FIG. 6 shows a top view of the structure of the memory device of FIG. 4 and FIG. 5A, including conductive contacts and memory cell pillars, according to some embodiments described herein.

FIG. 7 shows a side view (e.g., cross-section) of a portion of the memory device of FIG. 6, including conductive contacts associated with control gates of the memory device, according to some embodiments described herein.

FIG. 8A and FIG. 8B show details (e.g., side view and top view, respectively) of a conductive contact (e.g., word line contact) of the memory device of FIG. 7, according to some embodiments described herein.

FIG. 8C and FIG. 8D show alternative structures of the conductive contact of FIG. 8A, according to some embodiments described herein.

FIG. 9 shows a memory device that can be an alternative structure of the memory device shown in FIG. 6, according to some embodiments described herein.

FIG. 10A through FIG. 29D show different views of elements during processes of forming a memory device including forming conductive contacts of the memory device, according to some embodiments described herein.

FIG. 30A through FIG. 33D show different views of elements during alternative processes of forming a memory device including forming conductive contacts of the memory device, according to some embodiments described herein.

### DETAILED DESCRIPTION

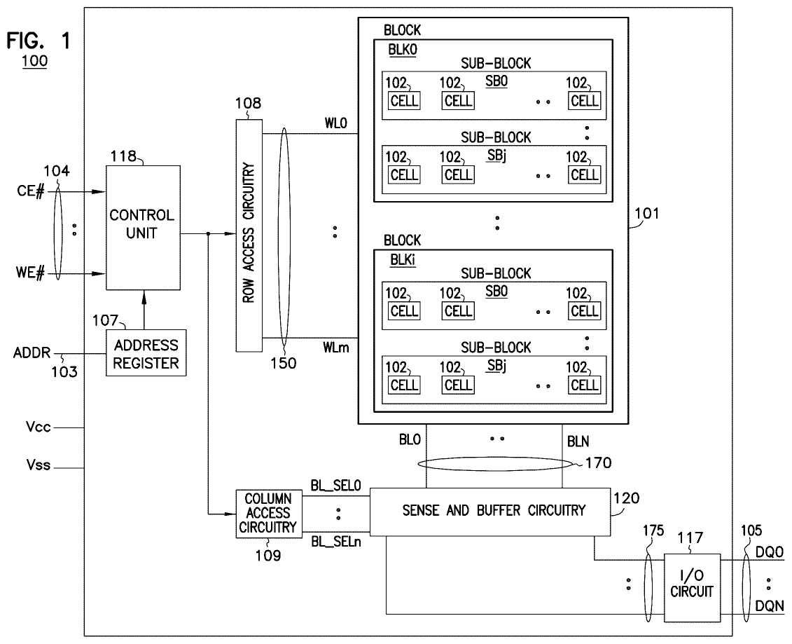

The techniques described herein involve a memory device including memory cells formed in tiers (different physical levels) of the memory device. The tiers include respective levels of conductive materials. The conductive materials form part of control gates (e.g., word lines) associated with the memory cells. The described memory device includes conductive contacts associated with the control gates. The structure of the conductive contacts have a segmented profile. The techniques described herein also involve processes of forming the described memory device. As described in more detail below, the techniques described herein can improve at least one of cost, performance, and reliability of the memory device. Other improvements and benefits of the techniques described herein are further discussed below with reference to FIG. 1 through FIG. 33D.

FIG. 1 shows a block diagram of an apparatus in the form of a memory device 100, according to some embodiments described herein. Memory device 100 can include a memory array (or multiple memory arrays) 101, containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE#, a write enable signal WE#) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

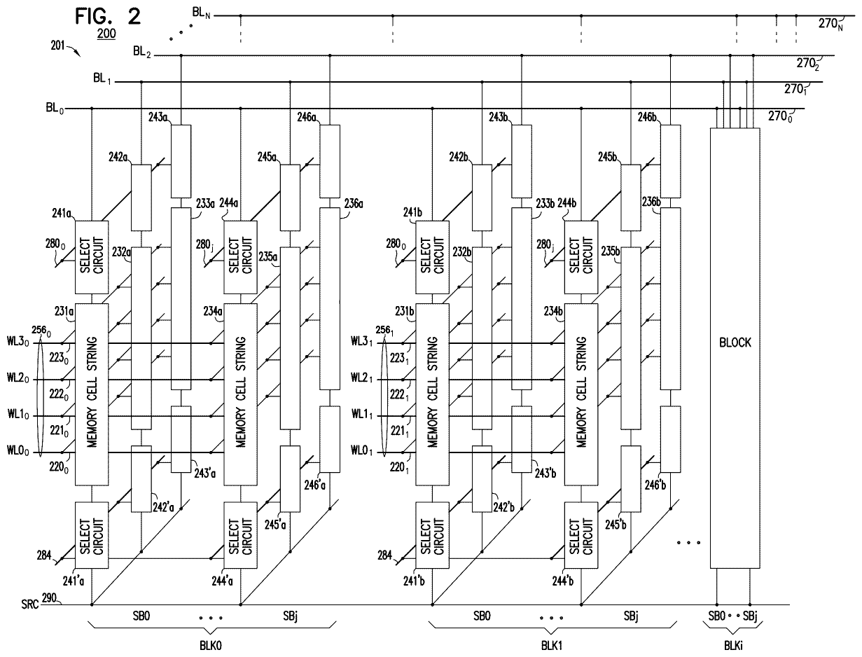

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 33D.

FIG. 2 shows a general schematic diagram of a portion of a memory device 200 including a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

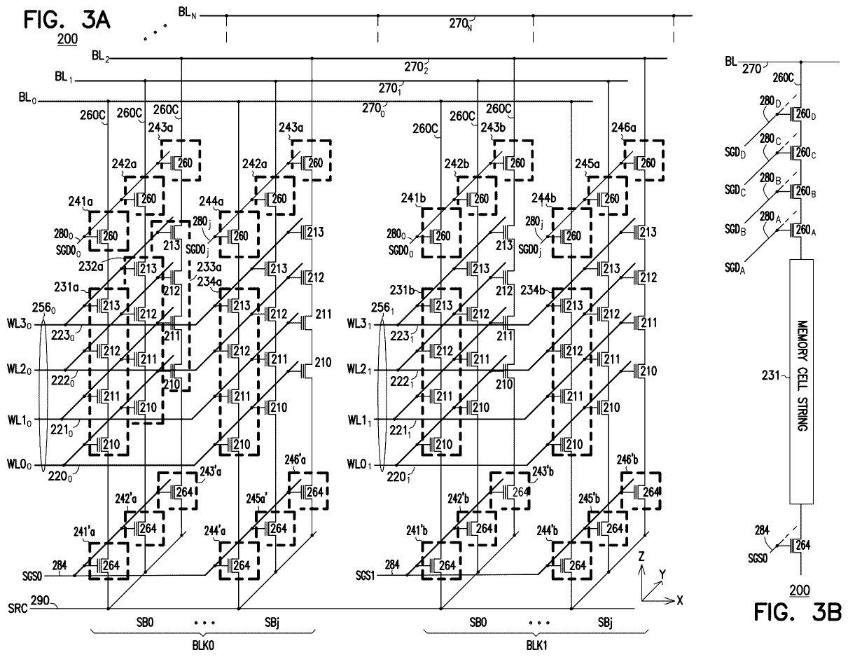

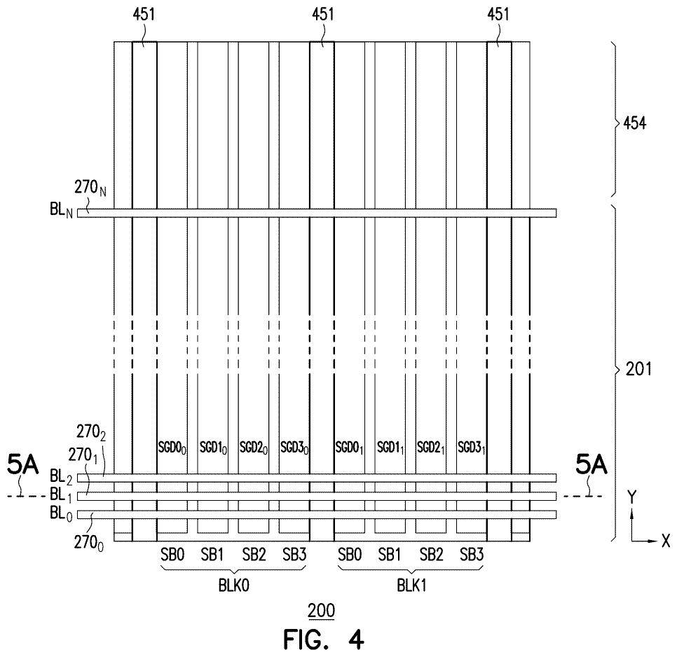

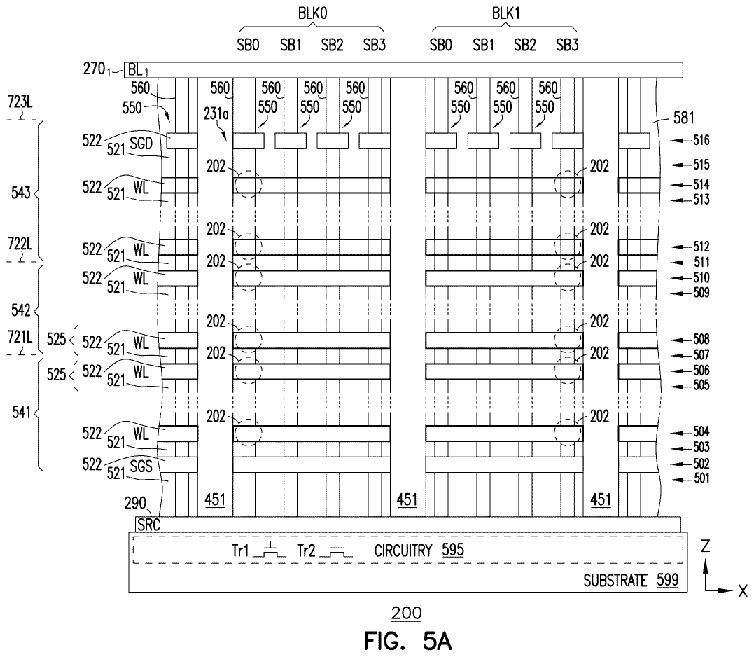

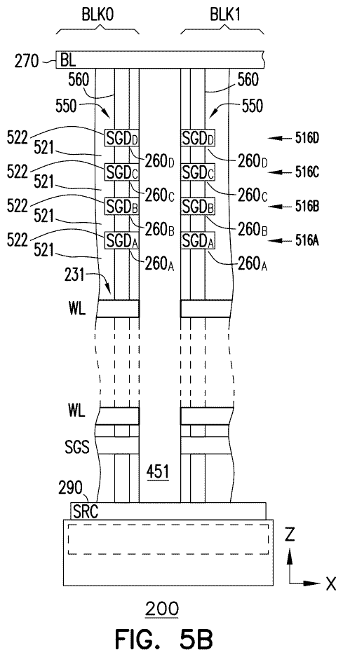

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3A and FIG. 4) and a pillar (e.g., pillar 550 in FIG. 5A) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK0 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3A) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3A) coupled between source 290 and a respective memory cell string. The source select gate (e.g., transistor) can be controlled (e.g., turned on or turned off) by a signal on a respective source select line based on a voltage provided to the signal.

FIG. 3A shows a detailed schematic diagram including blocks of the blocks BLK0 and BLK1 of memory device 200 of FIG. 2, according to some embodiments described herein. In FIG. 3A, directions X, Y, and Z in FIG. 3A can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5A). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3A. As shown in FIG. 3A, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3A, similar drain select lines (and their associated signals) are given the same labels for simplicity. However, as shown in FIG. 3A, the drain select lines (from the same block or from different blocks) of memory device 200 are electrically separated from each other and carry different signals (although the signals are given the same labels).

As shown in FIG. 3A, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3A, each of the memory cell strings (e.g., memory cell string 231a) of memory device 200 can include series-connected memory cells that include one of memory cells 210, one of memory cells 211, one of memory cells 212, and one of memory cells 213. FIG. 3A shows an example of four memory cells 210, 211, 212, and 213 in each memory cell string. The number of memory cells in each memory cell string can vary. For example, each memory string can include up to hundreds (or more) of memory cells.

As shown in FIG. 3A, memory device 200 can include conductive connections 260C coupled between respective select gates 260 and respective data lines 270₀ through 270_{N}. In the physical structure of memory device 200, each conductive connection 260C is part of a contact structure (e.g., contact structure 560 in FIG. 5A) associated with a memory cell pillar (e.g., pillar 550 in FIG. 5A) of memory device 200.

As shown in FIG. 3A, each drain select circuit (e.g., select circuit 241a) can include one of select gates 260. Each source select circuit (e.g., select circuit 241′a) can include one of select gates 264.

Each select gate 260 in FIG. 3A can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor [e.g., FET]) between the portion of the conductive material and the portion of the channel material.

FIG. 3A shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 3B shows an example of memory device 200 including four select gates (e.g., four drain select gates) 260_{A}, 260_{B}, 260_{C}, and 260_{D} associated with four select lines 280_{A}, 280_{B}, 280_{C}, and 280_{D}. Memory device 200 can use signals SGD_{A}, SGD_{B}, SGD_{C}, and SGD_{D} on select lines 280_{A}, 280_{B}, 280_{C}, and 280_{D}, respectively, to control (turn on or turn off) select gates 260_{A}, 260_{B}, 260_{C}, and 260_{D}, respectively. Data line 270 and associated signal BL can be one of data lines 270₀ through 270_{N} (FIG. 3A) associated with one of signals BL₀ through BL_{N}, respectively. Memory cell string 231 in FIG. 3B and associated with conductive connection 260C can be one of the memory cell strings (e.g., memory cell string 231a) associated with conductive connection 260C of memory device 200 of FIG. 3A.

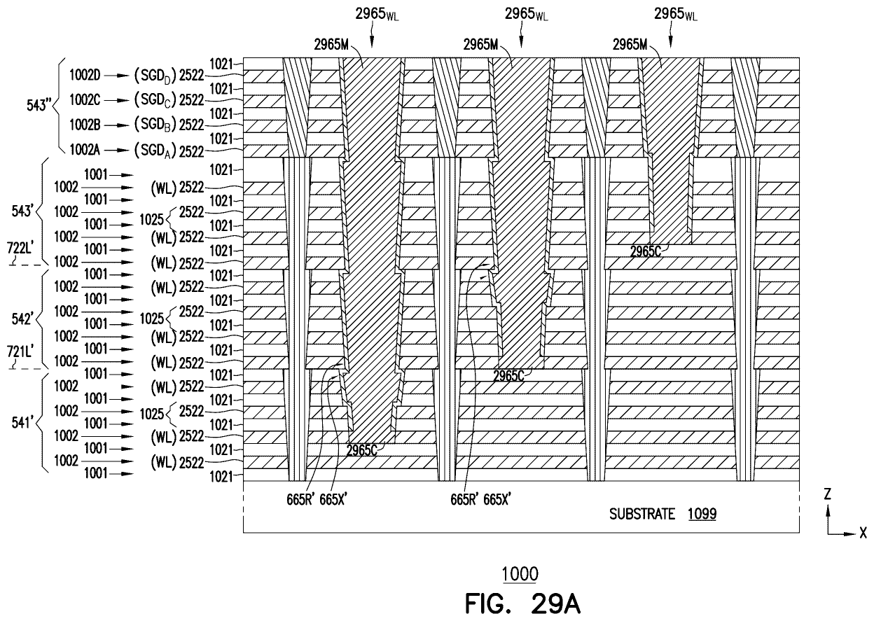

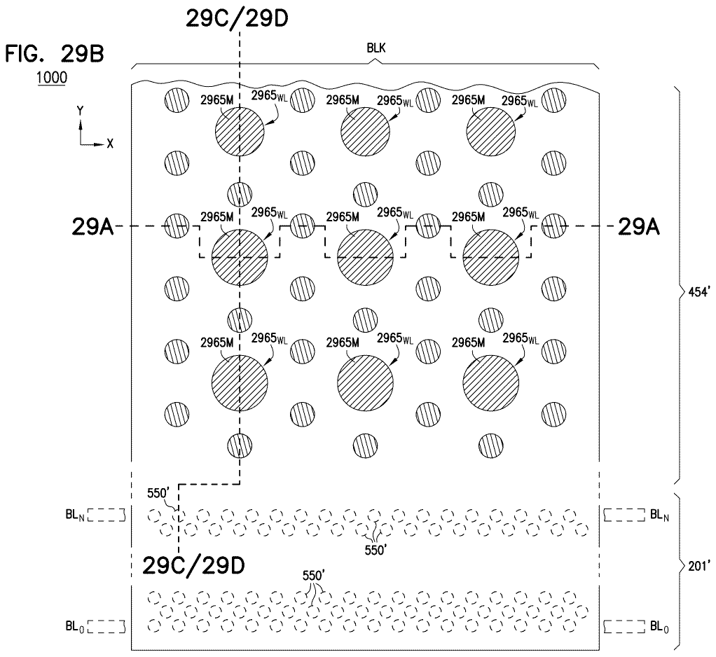

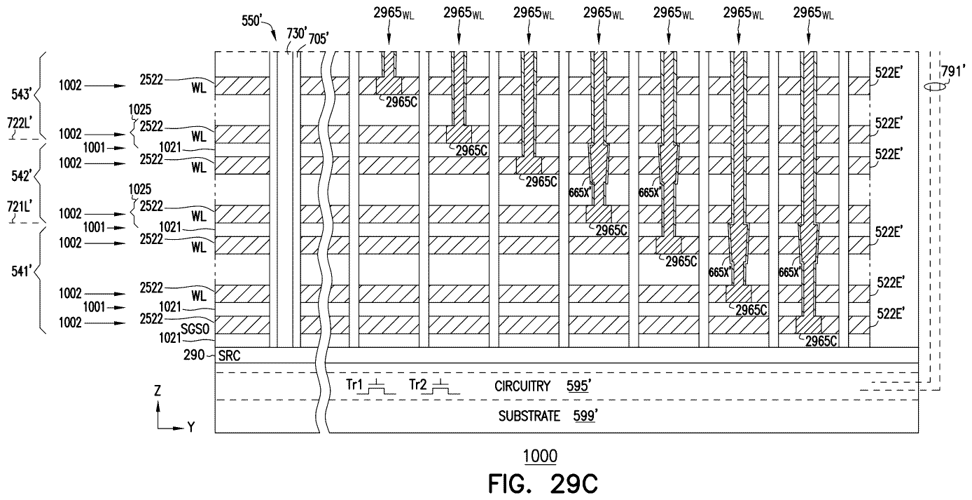

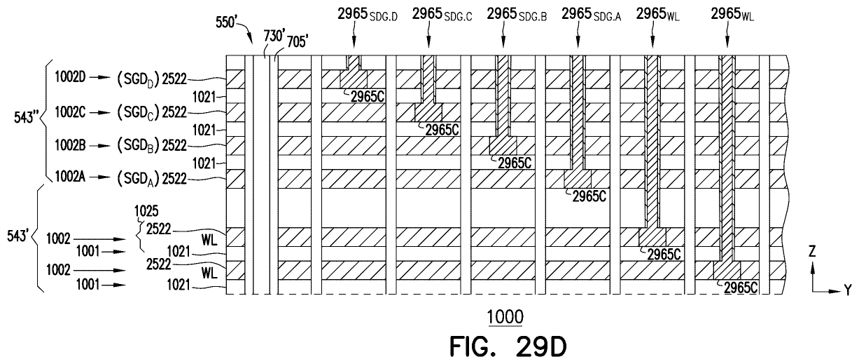

The structures of select lines 280_{A}, 280_{B}, 280_{C}, and 280_{D} can be similar to or the same as those of the select lines associated with signals SGD_{A}, SGD_{B}, SGD_{C}, and SGD_{D} of memory device 1000 in FIG. 29D. FIG. 3B shows one source select gate (e.g., select gate 264) and one source select signal (e.g., signal SGS0) on a source select line (e.g., select line 284). However, memory device 200 can include two or more source select gates (in the Z-direction, like select gates 260A, 260B, 260C, and 260D) that are connected in series with memory cell string 231.

FIG. 4 shows a top view of a structure of a portion of memory device 200 of FIG. 2 and FIG. 3A including a region of memory array 201 associated with blocks BLK0 and BLK1, a region 454, and structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3A are also not repeated.

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1). Structures 451 can be called dielectric structure or slit structures. The regions of memory device 200 at which structures 451 are located can be called slit regions.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have a structure like block BLK0. As shown in FIG. 4, block BLK1 can include sub-blocks SB0, SB1, SB2, and SB3, and select lines (e.g., drain select lines) SGD0₁, SGD1₁, SGD2₁, and SGD3₁.

As shown in FIG. 4, data lines 270₀ through 270_{N} of memory device 200 can be located over the region of memory array 201. Data lines 270₀ through 270_{N} can extend across (in the X-direction) the blocks (e.g., blocks BL0 and BL1).

A side view side view (e.g., cross-section) at memory array (memory cell array) 201 of memory device 200 along line 5A-5A (dashed line 5A) in FIG. 4 is shown in FIG. 5A.

FIG. 5A shows a side view (e.g., cross-section) of a structure of a portion of memory device 200 of FIG. 4 including tiers (tiers of materials) 525 that include respective memory cells 202 and control gates (associated with signals WL) associated with memory cells 202, according to some embodiments described herein. FIG. 5A also partially shows other blocks (on the left and right sides of blocks BLK0 and BLK1) of memory device 200.

As shown in FIG. 5A, memory device 200 can include a substrate 599, source 290 formed over substrate 599, and different levels 501 through 516 over substrate 599 in the Z-direction. Levels 501 through 516 are physical device levels of memory device 200 over substrate 599.

In FIG. 5A, for simplicity, control gates of blocks BLK0 and BLK1 are indicated by the same signal WL. For example, in block BLK0, the control gates indicated by signals WL can correspond to respective control gates associated with signals WL0₀, WL1₀, WL2₀, and WL3₀, respectively, of block BLK0 shown in FIG. 3A. In another example, in block BLK1 in FIG. 5A, the control gates indicated by signals WL can correspond to respective control gates associated with signals WL0₁, WL1₁, WL2₁, and WL3₁, respectively, of block BLK1 shown in FIG. 3A.

As shown in FIG. 5A, memory device 200 can include decks 541, 542, and 543. Each of decks 541, 542, and 543 can include part of memory devices 200 in different physical levels (e.g., levels 501 through 516) of memory device 200. For simplicity, FIG. 5A shows partial structures (e.g., broken lines in the Z-direction) of each of decks 541, 542, and 543. As shown in FIG. 5A, each of decks 541, 542, and 543 can include respective tiers 525 of memory cells 202 and associated control gates (associated with signals WL). FIG. 5A shows memory device 200 including three decks (e.g., decks 541, 542, and 543) as an example. However, the number of decks in memory device 200 can be different from three.

FIG. 5A also shows levels 721L, 722L, and 723L of memory device 200 that can represent example boundaries (e.g., inter-deck boundary) in the Z-directions among of decks 541, 542, and 543. For example, deck 541 can include a portion of memory device 200 between source 290 and level 721L. Deck 542 can include a portion of memory device 200 between level 721L and level 722L. Deck 543 can include a portion of memory device 200 between level 722L and level 723L. As shown in FIG. 7, level 721L (between decks 541 and 542) can be between two adjacent levels (e.g., levels 506 and 508) of conductive materials 522 that are located immediately next to each other. Level 722L (between decks 542 and 543) can be between two adjacent levels (e.g., levels 510 and 510) of conductive materials 522 that are located immediately next to each other.

Memory device 200 can include a dielectric material 581 formed over at least a portion of memory device 200. Memory cells 210, 211, 212, and 213 of the memory cell strings (e.g., memory cell string 231a in FIG. 3A) of respective sub-blocks SB0, SB1, SB3, and SB3 of each of blocks BLK0 and BLK1 can be formed over substrate 599 and source 290 (e.g., formed vertically in Z-direction in respective levels among levels 501 through 516).

As shown in FIG. 5A, data line 270₁ (associated with signal BL₁) can extend in the X-direction across the blocks (e.g., blocks BLK0 and BLK1 and other blocks) of memory device 200. Data line 270₁ can be shared by respective memory cell strings (including memory cell string 231a) of the blocks.

In FIG. 5A, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines on the same level 516) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5A, the select lines (e.g., four drain select lines on the same level 516) in the same block (e.g., block BLK0) can include respective conductive regions (e.g., four conductive regions) that are electrically separated from each other and can be located on the same level (e.g., level 516) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3A. In another example, in block BLK1, the select line indicated by signal SGS can correspond to the select line (e.g., source select line) associated with signals SGS1 of block BLK1 shown in FIG. 3A.

As shown in FIG. 5A, memory device 200 can include dielectric materials (e.g., silicon dioxide) 521 located on levels 503, 505, 507, 509, 511, 513, and 515. Dielectric materials 521 in a respective block are interleaved with conductive materials 522 in the respective block. Conductive materials 522 can form respective control gates (associated with signals WL) of a respective block. As shown in FIG. 5A, dielectric materials 521 can be located on respective levels among levels 501 through 516. Conductive materials 522 can be located on respective levels (e.g., levels 502, 504, 506, 508, 510, 512, 514, and 516) among levels 501 through 516 that are interleaved with the levels of dielectric materials 521. Examples of conductive materials 522 (which form the control gates) include a single conductive material (e.g., single metal, e.g., tungsten) or a combination of different layers of conductive materials. For example, each of the control gates of blocks BLK0 and BLK1 can include (e.g., multi-layers of) aluminum oxide, titanium nitride, tungsten, or other conductive materials.

The levels of dielectric materials 521 and the levels of conductive materials 522 can form tiers 525 of memory device 200. Each tier 525 can include a level of dielectric material 521 and a level of conductive material 522. For simplicity, only some of tiers 525 are labeled in FIG. 5A. As shown in FIG. 5A, tiers 525 can be located one over another and can include respective levels of memory cells 202 and control gates associated with the memory cells. For simplicity, the memory cells of memory device 200 in FIG. 5A are given the same label (memory cells 202). FIG. 5A shows a few tiers (e.g., only two tiers 525 are labeled) of memory device 200 as an example. However, memory device 200 can include up to hundreds of tiers (or more than hundreds of tiers).

As shown in FIG. 5A, memory device 200 can include pillars (memory cell pillars) 550 in blocks BLK0 and BLK1. Each of pillars 550 can be part of a respective memory cell string (e.g., memory cell string 231a). Memory cells 202 of the same memory cell string (e.g., memory cell string 231a) can correspond to memory cells 210, 211, 212, and 213 of the same memory cell string in FIG. 3A. Each of pillars 550 can have length extending through at least a portion of each of decks 541, 542, and 543 in the Z-direction (e.g., extending vertically the Z-direction) from substrate 599 between substrate 599 and data line 270₁. As shown in FIG. 5A, the Z-direction is also a direction at which the length of pillar 550 extends from one tier to another tier, which is also a direction from levels of dielectric materials 521 to levels of conductive materials 522.

As shown in FIG. 5A, memory device 200 can include contact structures (e.g., data line contact structures) 560. Each pillar 550 can be coupled to a data line by a respective contact structure 560. Each contact structure 560 can be considered as part of a respective pillar 550 and can include a conductive material (or conductive materials) to allow electrical signal between pillar 550 and a respective data line.

As shown in FIG. 5A, memory cells 210, 211, 212, and 213 of respective memory cell strings (e.g., memory cell string 231a) can be located in different levels (e.g., levels 504, 506, 508, 510, 512, and 514) in the Z-direction of memory device 200. The control gates (associated with signals WL) of each of blocks BLK0 and BLK1 can be located on the same levels (e.g., levels 504, 506, 508, 510, 512, and 514) at which memory cells 202 are located. Thus, memory cells 202 and the control gates of blocks BLK0 and BLK1 can be located along respective portions (e.g., portions on levels 504, 506, 508, 510, 512, and 514) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5A, memory device 200 can include circuitry 595 located in (e.g., formed in) substrate 599. At least a portion of the circuitry 595 can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5A, source 290 can include a conductive material (or materials, e.g., different levels of different materials) and can have a length extending in the X-direction. FIG. 5A shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL) of blocks BLK0 and BLK1. Alternatively, the select gates associated with signal SGS, SGD, or both have material (or materials) different from the material of the control gates.

FIG. 5B shows an example structure of memory device 200 of FIG. 5A including four select gates (e.g., four drain select gates) 260_{A}, 260_{B}, 260_{C}, and 260_{D} associated with a memory cell string (e.g., memory cell string 231). The other elements of memory device 200 of FIG. 5B can be the same as those of memory device 200 shown in FIG. 5A. Memory device 200 of FIG. 5B can represent the structure of memory device 200 that is schematically shown in FIG. 3B. FIG. 5B shows an example of memory device 200 including four select gates (e.g., four drain select gates in a sub-block) associated with signals SGD_{A}, SGD_{B}, SGD_{C}, and SGD_{D}. Conductive materials 522 on respective levels 516A, 516B, 516C, and 516D form the select lines (e.g., four select lines) associated with the select gates. Like memory device 200 of FIG. 5A, memory device 200 of FIG. 5B can include contact structures (e.g., data line contact structures) 560 associated with pillars (memory cell pillars) 550.

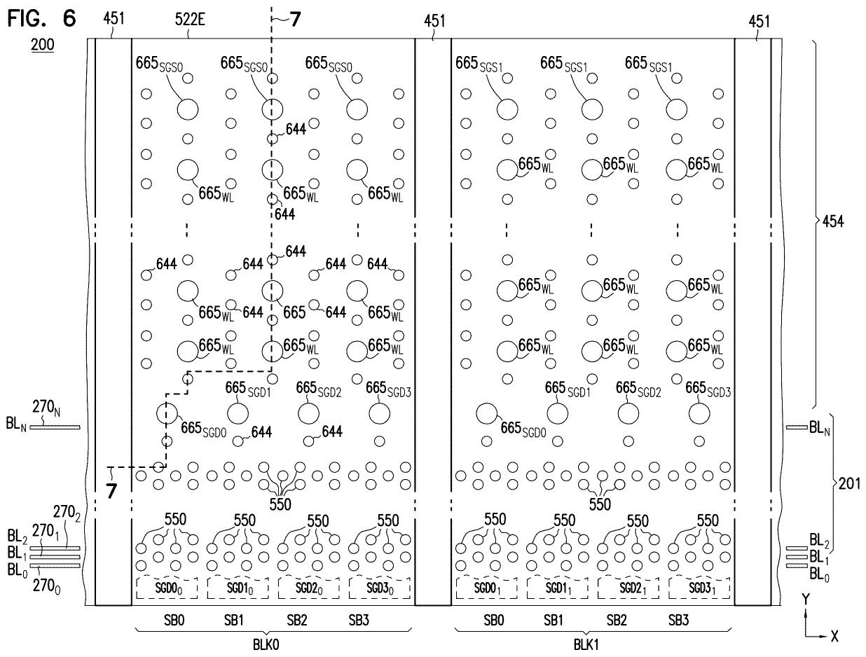

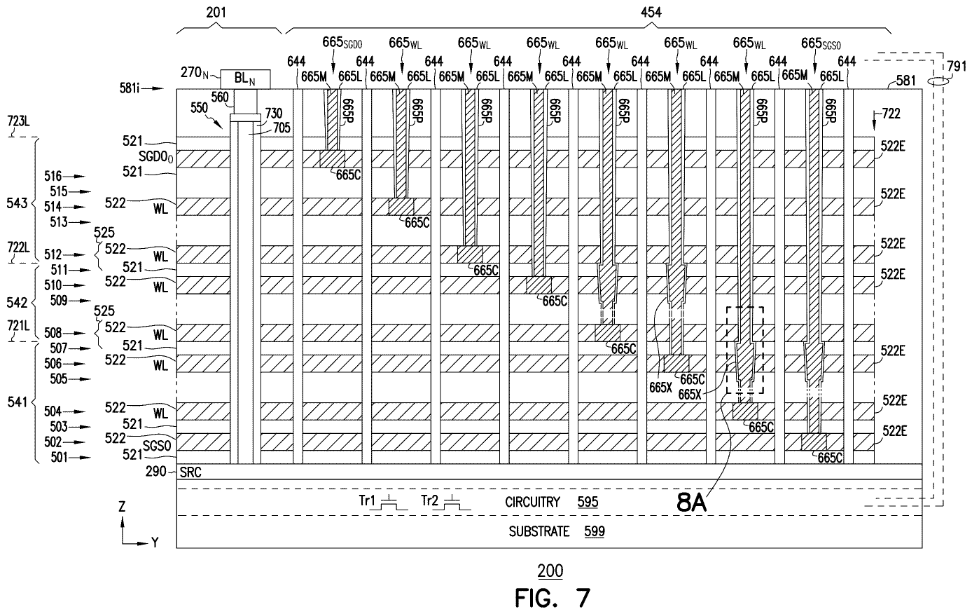

FIG. 6 shows more detail of the top view of the structure of memory device 200 of FIG. 4, according to some embodiments described herein. FIG. 6 shows top views of pillars 550 located in the region included in memory array 201, which is adjacent region 454. Region 454 can be called conductive contact region (e.g., word line conductive contact region) of memory device 200. As shown in FIG. 6, in region 454, memory device 200 can include conductive contacts (e.g., word line contacts) 665_{WL}, conductive contacts (e.g., drain select line contacts) 665_{SGDO}, 665_{SGD1}, 665_{SGD2}, and 665_{SGD3}), and conductive (e.g., source select line contact) 665_{SGS0}. Conductive contacts 665_{WL} can include metal (e.g., tungsten or other conductive materials). Although not shown in FIG. 6 for simplicity, memory device 200 can include conductive lines coupled to respective conductive contacts 665_{WL}. Such conductive lines can be part of conductive paths (e.g., conductive paths 791 in FIG. 7) coupled to components (e.g., word line drivers) of circuitry 595 (FIG. 7) of memory device 200.

In FIG. 6, conductive contacts 665_{WL} can contact (form electrical connection with) respective control gates (located under conductive contacts 665_{WL}, hidden from the top view of FIG. 6). Conductive contacts 665_{WL} can be part of respective access lines (e.g., word lines) of memory device 200. Conductive contacts 665_{WL} allow signals (e.g., signals WL0₀, WL1₀, WL2₀, and WL3₀ in block BLK0 in FIG. 3A) to be provided to respective control gates of block BLK0 through conductive contacts 665_{WL}. Each control gate in block BLK0 of FIG. 6 has an edge 522E. FIG. 7 (described in more detail below) shows side views (e.g., cross-sections) of conductive contacts 665_{WL} including edges 522E of respective control gates (associated with signals WL in FIG. 7) of memory device 200. FIG. 6 shows one edge 522E to indicate that edges 522E (shown in FIG. 7) may be aligned (e.g., vertically aligned) with each other in the Z-direction and are hidden from the top view of memory device 200 in FIG. 6.

Similarly, for block BLK1 in FIG. 6, conductive contacts (e.g., not labeled) can be formed at region 454 to allow signals (e.g., signals WL0₁, WL1₁, WL2₁, and WL3₁ in block BLK1 shown in FIG. 3A) to be provided to respective control gates of block BLK1 through the conductive contacts at region 454 of block BLK1.

In FIG. 6, the select lines associated with signals SGD0₀, SGD1₀, SGD2₀, and SGD3₀ in block BLK0 and signals SGD0₁, SGD1₁, SGD2₁, and SGD3₁ in block BLK1 are partially shown as dotted lines. Each of sub-blocks SB0, SB1, SB2, and SB3 can include multiple rows of pillars 550 associated with a respective select line (one of the select lines associated with signals SGD0₀, SGD1₀, SGD2₀, and SGD3₀). As shown in FIG. 6, the multiple rows of pillars 550 can be located one next to another (e.g., from left to right in FIG. 6) in the X-direction. Each row of pillars 550 can have a lengths parallel to the Y-direction. FIG. 6 shows an example where each sub-block includes four rows of pillars 550. However, the number of rows in the sub-blocks can be less than four or greater than four.

In FIG. 6, data lines 270₀ through 270_{N} are partially shown for simplicity. Data lines 270₀ through 270_{N} can extend across (in the X-direction) the blocks (e.g., blocks BL0 and BL1). Data lines 270₀ through 270_{N} can be located over and in electrical contact with pillars 550. Contact structures 560 (shown in FIG. 5A or FIG. 5B) coupled between pillars 550 and data lines 270₀ through 270_{N} are not shown in FIG. 6. Each pillar 550 in the same sub-block of a block can be coupled to a separate (e.g., unique) data line among data lines 270₀ through 270_{N}.

FIG. 6 also shows top views of dielectric pillars 644 (only few of dielectric pillars 644 are labeled). Each of dielectric pillars 644 can include a dielectric structure having lengths (shown in FIG. 7) extending the Z-direction. Dielectric pillars 644 can include dielectric materials (silicon dioxide), non-dielectric materials (e.g., semiconductor materials or conductive materials), or a combination of dielectric materials and non-dielectric materials.

Dielectric pillars 644 can be formed to provide structural support to a portion (e.g., region 454) of memory device 200 (e.g., support during part of the processes of forming memory device 200).

A side view (e.g., cross-section) along line 7-7 (dashed line 7) in FIG. 6 of block BLK0 is shown in FIG. 7.

FIG. 7 shows a side view of a portion of memory device 200 including conductive contacts 665_{WL}, 665_{SGDO}, and 665_{SGS0} in region 454, and pillar 550 in memory array 201, according to some embodiments described herein. Memory device 200 in FIG. 5A (in the X-Z direction) and in FIG. 7 (in the Y-Z direction) include the same elements (which have the same labels), including decks 541, 542, and 543, levels 501 through 516, and tiers 525. Levels 721L, 722L, and 723L are the same as those shown in FIG. 5A.

As shown in FIG. 7, each of decks 541, 542, and 543 can include a portion (e.g., a subset) of control gates of memory device 200. For example, deck 541 can include the control gates associated with signals WL between source 290 level 721L. Deck 542 can include the control gates associated with signals WL between levels 721L and 722L. Deck 543 can include the control gates associated with signals WL between levels 722L and 723L.

As shown in FIG. 7, conductive contacts 665_{WL} coupled to (e.g., contacting) the control gates associated with signals WL of deck 541 can extend (in the Z-direction) through deck 542 and 543 and at least partially through deck 541. Conductive contacts 665_{WL} coupled to (e.g., contacting) the control gates associated with signals WL of deck 542 can extend (in the Z-direction) through deck 543 and at least partially through deck 542 and may not extend below level 721L in the Z-direction. Conductive contacts 665_{WL} coupled to (e.g., contacting) the control gates associated with signals WL of deck 543 can extend (in the Z-direction) at least partially through deck 543 and may not extend below level 722L in the Z-direction (e.g., may not extend through deck 542 or through decks 542 and 541).

As shown in FIG. 7, pillar 550 can be located in the portion of memory device 200 that includes memory array 201, which is also shown in top view in FIG. 6. Pillar 550 can extend through conductive materials 522 (which form the control gates and the select lines) and dielectric materials 521 in the portions that include memory array 201.

As shown in FIG. 7, memory device 200 can include a structure 730 and a dielectric material 705 that can be part of pillar 550. Structure 730 and a dielectric material 705 can extend continuously (in the Z-direction) along the length of the respective pillar 550. Dielectric material 705 can include silicon dioxide. Structure 730 can be electrically coupled to source 290 and a respective data line (e.g., one of data line 270₀ through 270_{N} in FIG. 3A and FIG. 6). Structure 730 of a respective pillar 550 in a block is adjacent portions of respective control gates of that block.

Structure 730 can include a conductive structure that can be part of a conductive path (e.g., pillar channel structure) to conduct current between a respective data line (e.g., one of data line 270₀ through 270_{N} in FIG. 3A and FIG. 6) coupled to structure 730 and source 290. Structure 730 can also include a material (or materials) that can form a charge storage element (e.g., a memory element) of a respective memory cell (among memory cells 210, 211, 212, and 213) located along a portion of pillar 550. As an example, structure 730 can be part of an ONOS (SiO₂, Si₃N₄, SiO₂, Si) where Si₃N₄ material can form a charge storage element of a respective memory cell, and Si material can be part of the pillar channel structure of pillar 550. In another example, structure 730 can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure), where the floating gate structure can form a charge storage element of a respective memory (among memory cells 210, 211, 212, and 213) located along a portion of pillar 550.

As shown in FIG. 7, the control gates associated with signals WL, and the select lines associated with signals (e.g., drain select signal and source select signal) SGD0₀ and SGS0 can be structured (e.g., patterned), such that they may have the same length in the Y-direction. For example, the control gates (formed from respective conductive materials 522) associated with signals WL can have the same length (in the Y-direction) measuring between pillar 550 and edges 522E of respective the control gates. Edges 522E are part of respective conductive materials 522. As shown in FIG. 7, the control gates associated with signals WL can have the same length, such that edges 522E may be aligned (e.g., vertically aligned) with each other at a reference location (e.g., reference point), such as reference location 722 in the X-direction.

Thus, as shown in FIG. 7, a conductive contacts (e.g., conductive contact 665_{WL}) can be between pillar 550 and an edge 522E of a respective control gate and also between pillar 550 and an edge 522E of at least one control gate located above (in the Z-direction) the respective control gate. For example, the conductive contact 665_{WL} associated with the control gate on level 504 is between pillar 550 an edge 522E of conductive material 522 on level 504 and also between pillar 550 and edge 522E of conductive material 522 on level 506.

In another example, the conductive contact 665_{WL} associated with the control gate on level 506 is between pillar 550 and edge 522E of conductive material 522 on level 506 and also between pillar 550 and edge 522E of conductive material 522 on level 508.

As shown in FIG. 7, conductive contacts (e.g., word line contacts) 665_{WL}, conductive contact (e.g., drain select line contact) 665_{SGD0}, and conductive contact (e.g., source select line contact) 665_{SGS0} can include respective pillars (conductive pillars) 665P. Pillars 665P can include different (unequal) lengths extending in the Z-direction. The length of a particular conductive contact 665_{WL} (which is also the length of its associated pillar 665P) can be a distance (the measurement) in the Z-direction from the control gate associated with that particular conductive contact to a reference location (e.g., the reference location at level 581i) in memory device 200. For purposes of measuring the lengths of different conductive contacts (e.g., conductive contact 665_{WL}) in this description, the same reference location (e.g., at level 581i) with respect to the Z-direction is used for the length measurement.

For example, as shown in FIG. 7, the length of the conductive contact 665_{WL} coupled to the control gate on level 504 can be the distance (the measurement) in the Z-direction from level 581i to level 504. In another example, as shown in FIG. 7, the length of the conductive contact 665_{WL} coupled to the control gate on level 506 can be the distance (the measurement) in the Z-direction from level 581i to level 506.

As shown in FIG. 7, each conductive contact 665_{WL} can include conductive material 665M (that forms pillar 665P) that extends through (e.g., goes through) respective portions of dielectric materials 521 and conductive materials 522. Each conductive contact (e.g., conductive contact 665_{WL}, 665_{SGD0}, or 665_{SGS0}) can include a conductive pad 665C contacting to one of the conductive materials 522. Each conductive contact (e.g., conductive contact 665_{WL}, 665_{SGD0}, or 665_{SGS0}) can include a liner (dielectric liner) 665L to separate (electrically isolate) the conductive contact from conductive materials 522 except for one of the conductive material 522 that forms the control gate associated with the conductive contact. Liner 665L can include silicon dioxide or other dielectric materials (e.g., high-K dielectric materials, which have a dielectric constant greater than the dielectric constant of silicon dioxide).

As shown in FIG. 7, dielectric pillars 644 can include respective lengths extending in the Z-direction (e.g., extending through tiers 525). Dielectric pillars 644 can contact (e.g., lands on) on the material of source 290. Dielectric pillars 644 are electrically separated (electrically decoupled from) the control gates (associated with signals WL) and other elements (e.g., source 290) of memory device 200.

As shown in FIG. 7, dielectric pillars 644 can extend through (e.g., go through) dielectric materials 521 and conductive materials 522 of decks 541, 542, and 543. Dielectric pillars 644 can have the same lengths (e.g., same heights).

The length of each dielectric pillar 644 can be measured from source 290 to an end portion (e.g., top portion) of dielectric pillar 646 that can be located at level 781i (or above level 781i) in the Z-direction.

As shown in FIG. 7, memory device 200 can include conductive paths (e.g., conductive routings) 791 to form circuit paths between circuitry 595 and other elements of memory device 200. For example, conductive contact 665_{WL}, 665_{SGD0}, or 665_{SGS0} can be coupled to circuitry 595 through conductive paths 791. This allows electrical communication to between the control gates (associated with signals WL) and circuitry 595 through conductive contact 665_{WL}, 665_{SGD0}, and 665_{SGS0} and conductive paths 791 (FIG. 7).

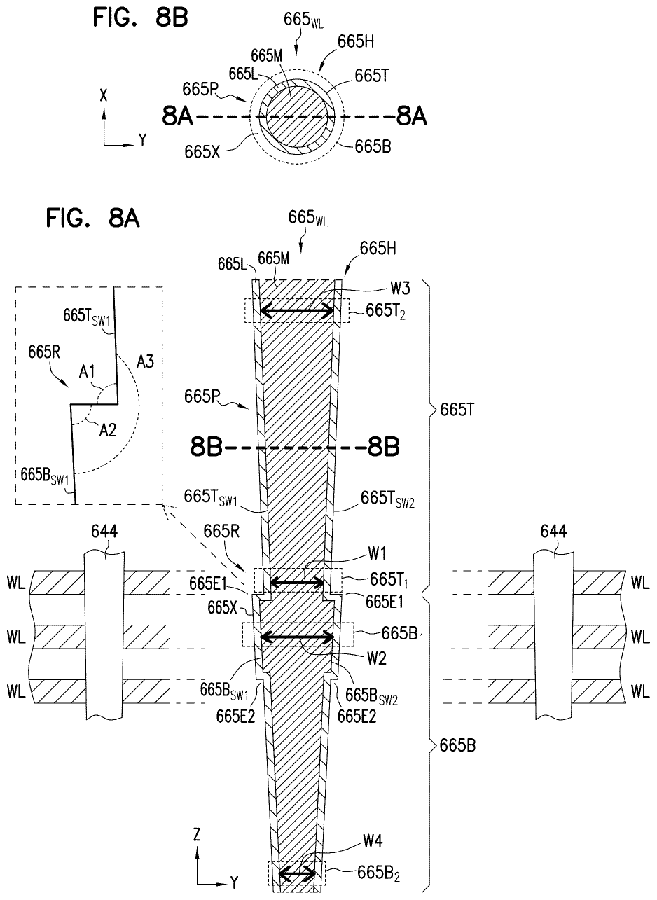

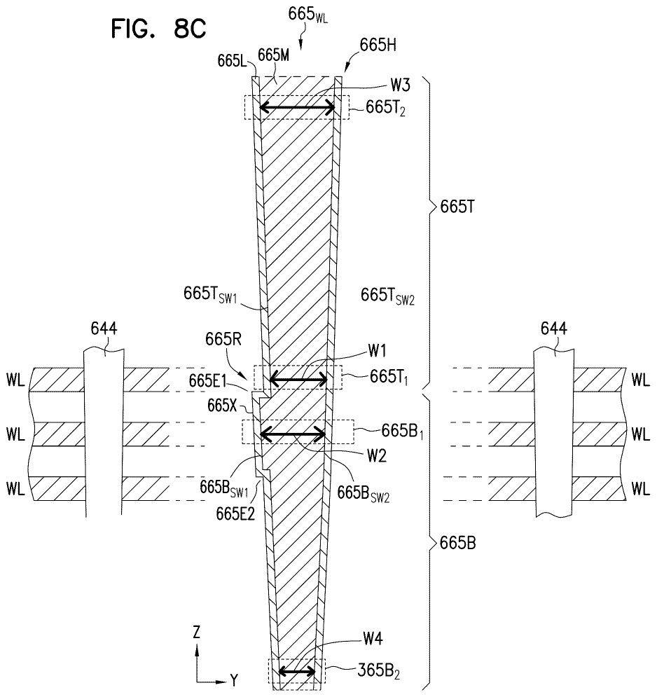

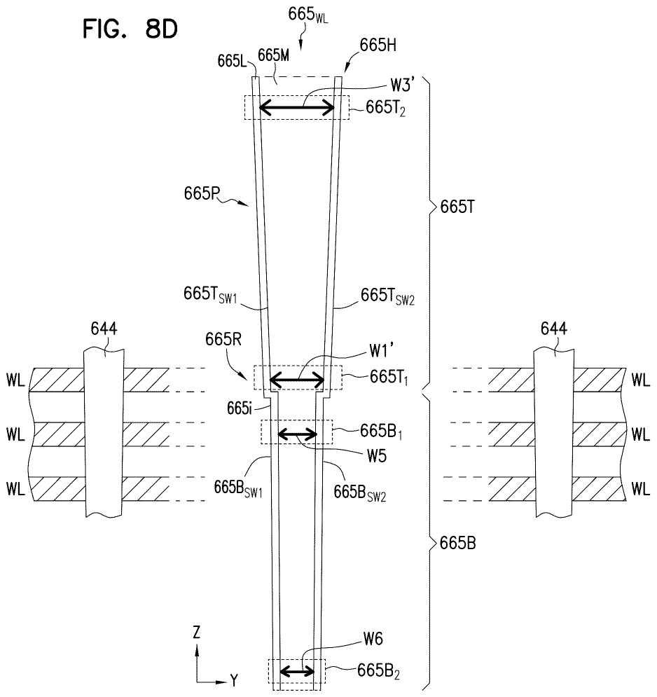

As shown in FIG. 7, the conductive contacts (e.g., conductive contacts 665_{WL}) have a segmented profile (e.g., not a straight profile) in the Z-direction. For example, some of the conductive contacts (e.g., conductive contacts 665_{WL}) in some of the decks (e.g., decks 541 and 542) of memory device 200 can have respective protrusions (protruding portions) 665X. A portion 8A of memory device 200 is shown with details in an enlarged view (e.g., enlarged cross-section) in FIG. 8A.

FIG. 8A and FIG. 8B show details (e.g., side view and top view, respectively) of portion 8A of conductive contact 665_{WL} associated with the control gate on level 504 of memory device 200 of FIG. 7, according to some embodiments described herein.

FIG. 8A shows detail of a portion (e.g., a side view (a cross-section perpendicular to the X-Y plan)) of part of conductive contact 665_{WL} including pillar 665P. FIG. 8B shows a top view (e.g., a cross-section parallel to the X-Y plane) along line 8B-8B (dashed line 8B) of FIG. 8A. The following description refers to FIG. 8A and FIG. 8B.

As shown in FIG. 8A and FIG. 8B, part of pillar 665P of conductive contact 665_{WL} can extend through some control gate (associated with signals WL). For simplicity, FIG. 8A show some of the control gates in dashed lines. FIG. 8A also shows dielectric pillars 644 adjacent conductive contact 665_{WL} that can extend the control gate (associated with signals WL).

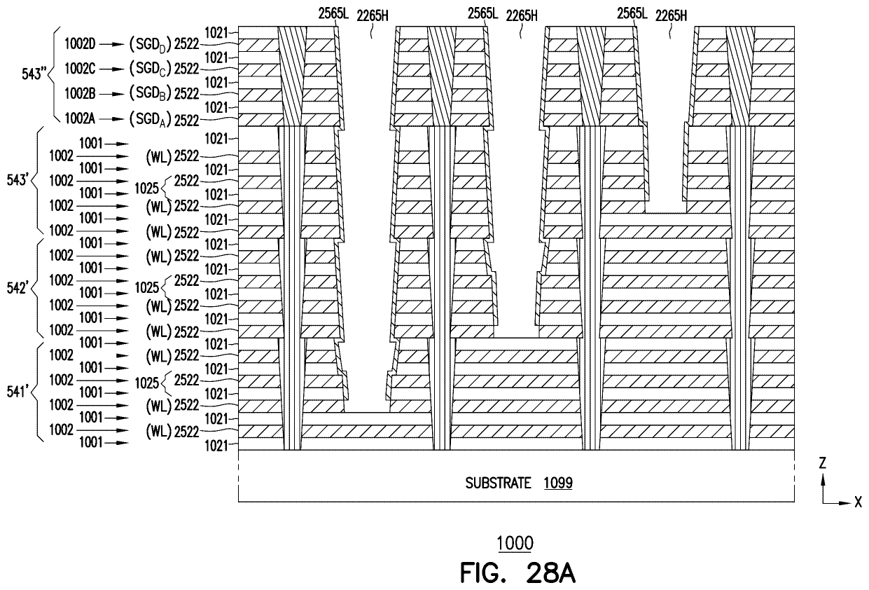

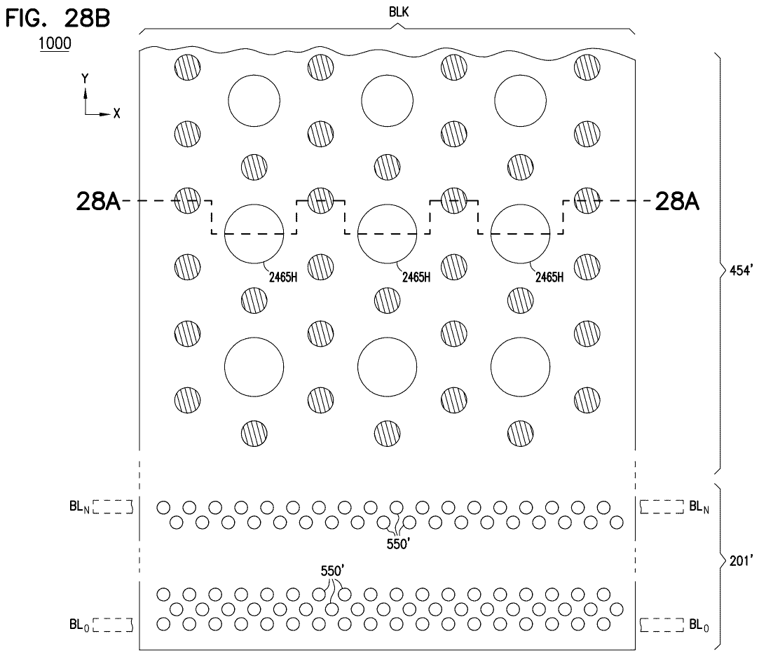

As shown in FIG. 8A and FIG. 8B, conductive contact 665_{WL} (including pillar 665P) can be formed in an opening (e.g., hole) 665H (which can be similar to one of openings 2465H of FIG. 28A). As shown in FIG. 8A and FIG. 8B, pillar 665P can include liner 665L and conductive material 665M and formed in opening 665H. As shown in FIG. 8B, conductive material 665M can be surrounded by liner 665L. Conductive material 665M can include metal (e.g., tungsten), an alloy, or combination of metal and alloy, or other conductive materials.

As shown in FIG. 8A and FIG. 8B, conductive contact 665_{WL} can include a portion (e.g., top portion) 665T joining (coupled to) a portion (e.g., bottom portion) 665B. As shown in FIG. 8A and FIG. 7, portion 665T is located over portion 665B in the Z-direction with respect to substrate 599 (FIG. 7) of memory device 200. As shown in FIG. 8A and FIG. 7, portion 665T is between portion 665B and the level (e.g., level 581i in FIG. 7) of memory device 200 at which the data lines (e.g., data line 270_{N} in FIG. 7) are located. As shown in FIG. 8A and FIG. 7, portion 665B is between portion 665T and source 290 (or substrate 599 in FIG. 7) of memory device 200.

As shown in FIG. 8A, portion 665B is between portion 665T and the control gate on level 504 (FIG. 7) that is associated with (e.g., coupled to) conductive contact 665_{WL} (FIG. 8A). As shown in FIG. 8A, portion 665T can have a sidewall 665T_{SW1} and a sidewall 665T_{SW2} opposite (e.g., in the Y-direction) sidewall 665T_{SW1}. Portion 665B can have a sidewall 665B_{SW1} and a sidewall 665B_{SW2} opposite (e.g., in the Y-direction) sidewall 665B_{SW1}.

As shown in FIG. 8A, protrusion 665X can include portions 664E1 and 665E2 that extend (e.g., extend laterally) in the Y-direction from respective the sidewalls of conductive contact 665_{WL}. For example, as shown in FIG. 8A, portions 665E1 of protrusion 665X can extend in the Y-direction from respective sidewalls 665T_{SW1} and 665T_{SW2} of portion 665T of conductive contact 665_{WL}. In another example, as shown in FIG. 8A, portions 665E2 of protrusion 665X can extend in the Y-direction from respective sidewalls 665B_{SW1} and 665B_{SW2} of portion 665B of conductive contact 665_{WL}.

As shown in FIG. 8A, conductive contact 665_{WL} can have widths W1, W2, W3, and W4 at different regions 665T₁, 665T₁, 665B₁, and 665B₂. Width W1 can be measured from sidewall 665T_{SW1} to sidewall 665T_{SW2} of region 665T₁ of portion 665T. Width W2 can be measured from sidewall 665B_{SW1} to sidewall 665B_{SW2} of region 665B₁ of portion 665B. Width W3 can be measured from sidewall 665T_{SW1} to sidewall 665T_{SW2} of region 665T₂ in portion 665T. As shown in FIG. 8A, conductive contact 665_{WL} can have a protrusion 665X, such that region 665B₁ is between region 665T₁ and region 665B₂ and such that width W2 is greater than width W1 and greater than width W3.

Width W4 can be measured from sidewall 665B_{SW1} to sidewall 665B_{SW2} of region 665B₂ in portion 665B. As shown in FIG. 8A, the structure of conductive contact 665_{WL} can have a physical profile, such that width W3 is greater than width W1 and greater than width W4.

As shown in FIG. 8A and FIG. 8B, conductive contact 665_{WL} can have a region 665R at which protrusion 665X is located. Region 665 is located between portions 665T and 665B of conductive contact 665_{WL.} Region 665R can also be a region between two decks of memory device 200. For example, region 665R can be at level 721L (or at level 722L) of memory device 200 of FIG. 7.

FIG. 8A also shows an enlarged portion of conductive contact 665_{WL} including region 665R. As shown in FIG. 8A, region 665R is located at a region of conductive contact 665_{WL} where a transition from sidewall 665T_{SW1} to sidewall 665B_{SW1} (or from sidewall 665T_{SW2} to sidewall 665B_{SW2}) does not follow the same angle A1 (e.g., does not follow the same sidewall slope). As shown in FIG. 8A, the transition from sidewall 665T_{SW1} to sidewall 665B_{SW1} at region 665R can have an angle A2 (or angle A3) that is different from angle A1.

The presence of region 665R including protrusion 665X in conductive contact 665_{WL} and in some of the other conductive contacts (e.g., other conductive contacts 665_{WL} shown in FIG. 7) of memory device 200 can be the result of improved processes (e.g., methods) of forming conductive contacts associated with control gates of a memory device (e.g., memory device 200 or 1000), as described below with reference to FIG. 10A through FIG. 33D.

FIG. 8C and FIG. 8D show alternative structures of the conductive contact 665_{WL} of FIG. 8A, according to some embodiments described herein. As shown in FIG. 8C and FIG. 8D, conductive contacts 665_{WL} can have a segmented profile like conductive contacts 665_{WL} of FIG. 8A. Differences between conductive contacts 665_{WL} in FIG. 8A, FIG. 8C, and FIG. 8D are describe below.

As shown in FIG. 8A, protrusion 665X of conductive contacts 665_{WL} may be present on both sides of conductive contacts 665_{WL} in the Y-direction in the cross-sectional view in FIG. 8A (e.g., protrusion 665X may be symmetrical in the Y-direction in the cross-sectional view in FIG. 8A). However, in the alternative structure of memory device 200 of FIG. 8C, protrusion 665X of conductive contacts 665_{WL} may be present on one side (e.g., on only one side of conductive contacts 665_{WL} in the Y-direction in the cross-sectional view in FIG. 8A (e.g., protrusion 665X may be asymmetrical in the Y-direction in the cross-sectional view in FIG. 8A). For example, as shown in FIG. 8C, protrusion 665X can include portions 664E1 and 665E2 that extend (e.g., extend laterally) in the Y-direction from respective sidewalls 665T_{SW1} and sidewall 665B_{SW1} of conductive contact 665_{WL}.

FIG. 8D show an alternative structure of the conductive contact 665_{WL} of FIG. 8A in which widths W1′ and W3′ can be similar to (or the same as) widths W1 and W3, respectively of FIG. 8A. As shown in FIG. 8D, conductive contacts 665_{WL} can have an intruding portion 665i that has a different profile (different structure) from protrusion 665X of conductive contacts 665_{WL} in FIG. 8A and FIG. 8C. For example, in FIG. 8D, intruding portion 665i of conductive contacts 665_{WL} may extend laterally in the Y-direction towards the center of conductive contacts 665_{WL}. As shown in FIG. 8D, the structure of conductive contact 665_{WL} can have a physical profile, such that width W1′ in region 665T₁ is greater than width W5 of region 665B₁ (at intruding portion 665i) and greater than width W6 of region 665B₂.

Memory device 200 including conductive contacts (e.g., conductive contacts 665_{WL} shown in FIG. 7, FIG. 8A, FIG. 8C, and FIG. 8D) as described above include improvements and benefits similar to those of memory devices 1000 and 3000 described below.

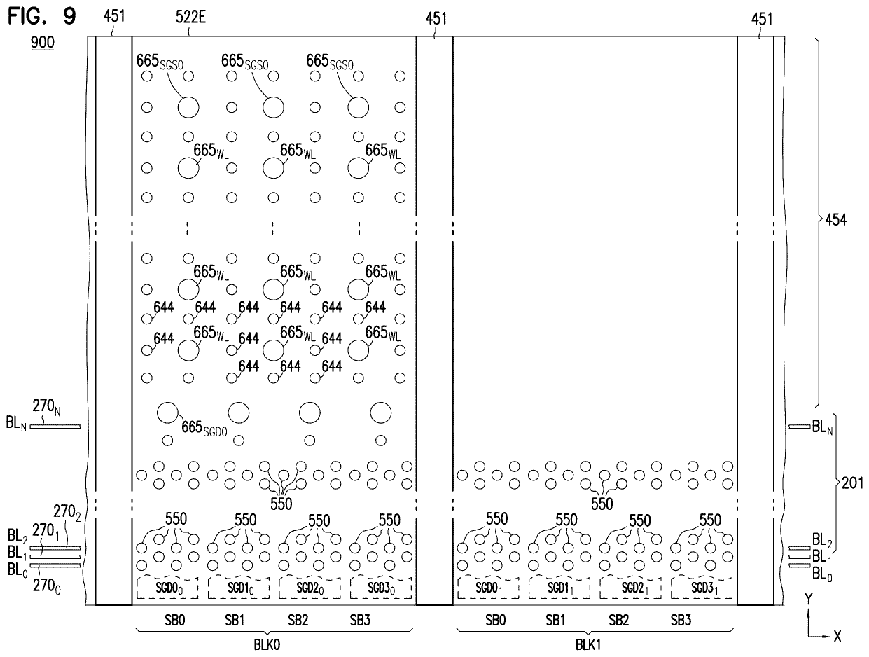

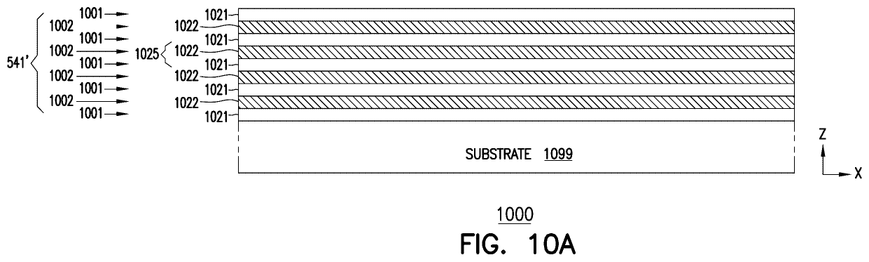

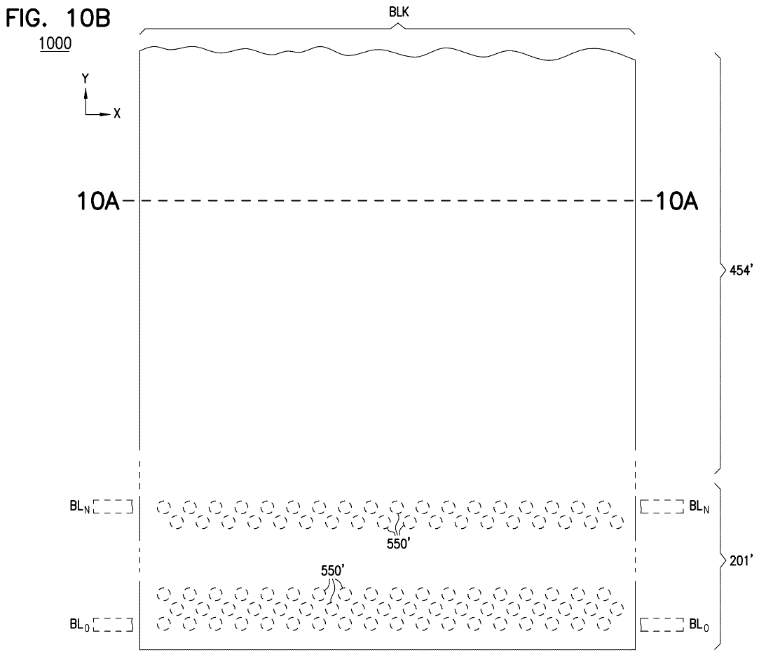

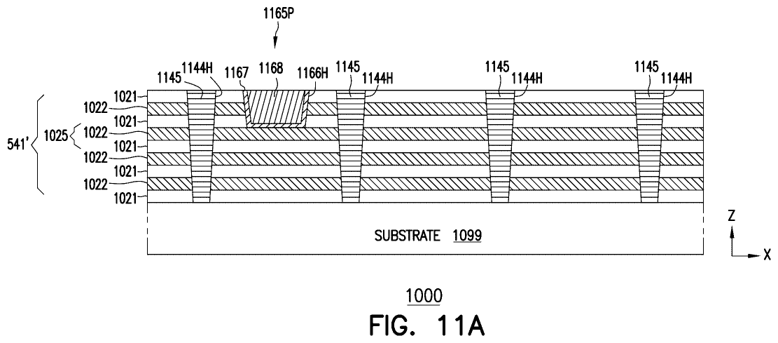

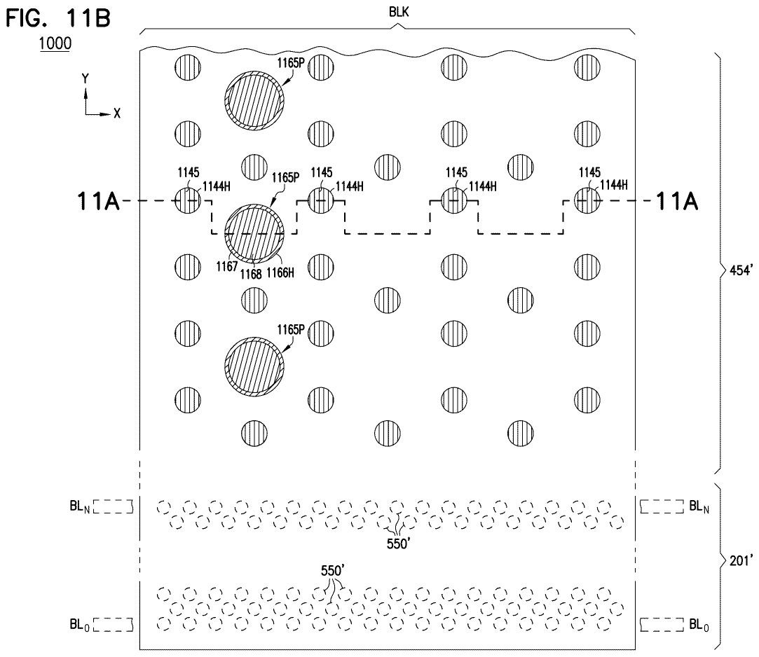

FIG. 9 shows a memory device 900 that can be an alternative structure of the memory device shown in FIG. 6, according to some embodiments described herein. As shown in FIG. 9 and FIG. 6, memory device 900 can include elements that are similar to or the same as the elements of memory device 200. For simplicity, descriptions of similar or the same elements between memory devices 200 and 900 are not repeated. As shown in FIG. 9, memory device 900 includes conductive contacts (e.g., conductive contacts 665_{WL}) like the conductive contacts of memory device 200 shown in FIG. 6.

In comparison with memory device 200 (FIG. 6), memory device 900 (FIG. 9) can have patterns (e.g., straight patterns) of dielectric pillars 644 that are different from the patterns (e.g., staggered patterns) of dielectric pillars 644 of memory device 200 (FIG. 6). Improvements and benefits of memory device 900 are similar to or the same as improvements and benefits of memory device 200.

The arrangement of the conductive contacts (e.g., conductive contacts 665_{WL} and 665_{SGS0}), or dielectric pillars 644, or both of the memory devices described above (e.g., memory device 200 in FIG. 6 and memory device 900 in FIG. 9) are examples. However, conductive contacts (e.g., conductive contacts 665_{WL} and 665_{SGS0}), or dielectric pillars 644, or both can have other arrangements different from those shown in FIG. 6 and FIG. 9.

The above description with reference to FIG. 2 through FIG. 9 describes the structure of memory devices 200 and 900. Some or all of the structure of memory devices 200 and 900 can be formed using processes associated with the processes described below with reference to FIG. 10A through FIG. 33D.

FIG. 10A through FIG. 29D show different views of elements during processes of forming a memory device 1000, according to some embodiments described herein. FIG. 10A shows a side view (e.g., cross-section) in the X-direction of a portion of memory device 1000. FIG. 10B shows a top view (e.g., X-Y plane view) of memory device 1000. FIG. 10A shows a side view (e.g., cross-section) of memory device 1000 taken along line 10A-10A (dashed line 10A) in region 453′ of FIG. 10B. Regions 454′ of memory device 1000 is similar to region 454 (e.g., word line conductive contact region) of memory device 200 in FIG. 6.

FIG. 10B also shows a region (memory array region) 201′, which is similar to the region included in memory array 201 of memory device 200 in FIG. 6. FIG. 10B also shows locations (from top view) of pillars 550′ associated with the memory cells of memory device 1000 in region 201′ and the data lines (associated with signals BL..0 through BL..N) of memory device 100. For simplicity, the description here omits processes that form pillars 550′ associated with the memory cells of memory device 1000 and process that form the data lines of memory device 1000.

The processes associated with FIG. 10A can include forming dielectric materials (levels of dielectric materials) 1021 on levels 1001 and dielectric materials (levels of dielectric materials) 1022 on levels 1002 over substrate 1099.

Levels 1001 (multiple levels 1001) and levels 1002 (multiple levels 1002) are physical levels of the structure of memory device 1000. Dielectric materials 1021 can include silicon dioxide. Dielectric materials 1022 can include silicon nitride. Dielectric materials 1021 and 1022 can be sequentially formed one material after another over substrate 1099 in an interleaved fashion, such that dielectric materials 1021 can be interleaved with dielectric materials 1022 in the Z-direction over substrate 1099.

In FIG. 10A, substrate 1099 is similar to (e.g., can correspond to) substrate 599 of memory device 200 shown in FIG. 5A and FIG. 7. For simplicity FIG. 10A (and other subsequent figures) omits a portion (portion in dashed line) between substrate 1099 and dielectric materials 1021 and 1022.

As shown in FIG. 10A, dielectric materials 1021 and 1022 can form tiers (tiers of materials) 1025. Tiers 1025 are located one over another in the Z-direction. Each tier 1025 can include a respective level of dielectric material 1021 and a respective level of dielectric material 1022. The thickness (in the Z-direction) of one tier 1025 can be the combination of thickness (in the Z-direction) of a level 1001 and a thickness (in the Z-direction) of an adjacent level 1002. Thus, in FIG. 10A, the thickness (in the Z-direction) of one tier 1025 can be the combination of thickness (in the Z-direction) of a level of dielectric materials (e.g., silicon dioxide) 1021 and a level of dielectric materials (e.g., silicon nitride) 1022.

As shown in FIG. 10A, tiers 1025 can be included in a deck 541′ of memory device 1000. The processes of forming memory device 1000 (FIG. 10A through FIG. 29D) can also form decks 542′ and 543′ (described below). Decks 541′, 542′, and 543′ of memory device 1000 can correspond to decks 541, 542, and 543 of FIG. 5A and FIG. 7.

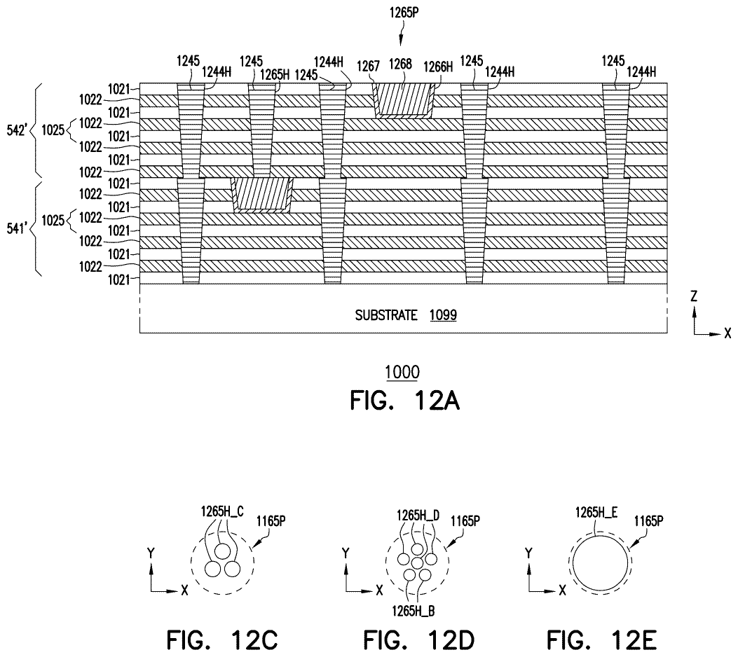

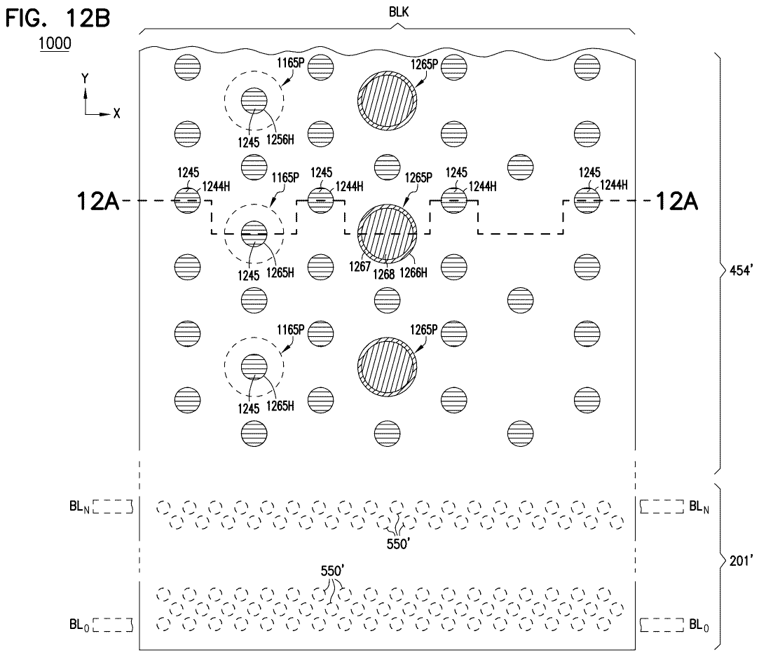

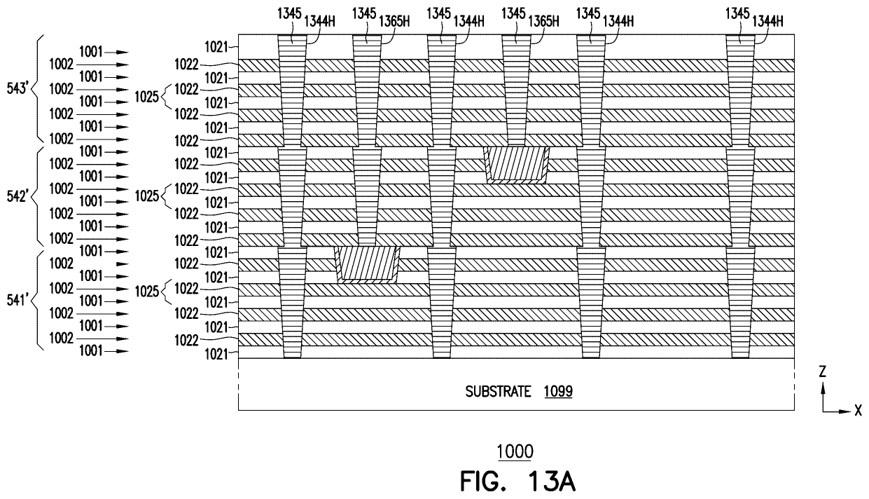

In the following description of FIG. 11A through FIG. 29D, the views of memory device 1000 shown in FIG. 11A through FIG. 29D follow the same pattern of views of FIG. 10A and FIG. 10B. For example, FIG. 11A shows a similar view (e.g., top view of memory device 1000) of FIG. 10A. FIG. 11B shows a similar view (e.g., side view of memory device 1000) of FIG. 10B. Line 11A-11A (cross-section line) in FIG. 11B shows the location of the view of memory device 1000 of FIG. 11A. In another example, FIG. 12A shows a similar view (e.g., top view of memory device 1000) of FIG. 11A. FIG. 12B shows a similar view (e.g., side view of memory device 1000) of FIG. 11B. Line 12A-12A (cross-section line) in FIG. 12B shows the location of the view of memory device 1000 of FIG. 12A.

FIG. 11A and FIG. 11B show memory device 1000 after formation of openings 1144H, material 1145, and structures 1165P in region 454′ in deck 541′. In subsequent processes of forming memory device 1000, part of conductive contacts of memory device 1000 (like conductive contacts 665_{WL} of memory device 200 of FIG. 6 and FIG. 7) can be formed at respective locations of respective structures 1165P. In subsequent processes of forming memory device 1000, part of support structures contacts of memory device 1000 (like dielectric pillars 644 memory device 200 of FIG. 6 and FIG. 7) can be formed at the locations of openings 1144H.

In FIG. 11A and FIG. 11B, forming openings 1144H can include removing (e.g., etching) a portion of dielectric materials 1021 and 1022 at the locations of openings 1144H. Then, dielectric material 1145 can be formed (e.g., filled) in openings 1144H. In subsequent processes of forming memory device 1000, material 1145 can be removed from openings 1144H. Thus, material 1145 can be called a sacrificial material. Material 1145 can be different from dielectric materials 1021 and 1022. An example of material 1245 can include carbon or other materials.

Forming structures 1165P can include removing (e.g., etching) a portion of dielectric materials 1021 and 1022 to form openings (e.g., holes) 1166H at the locations of structures 1165P. Then, liners 1167 can be formed on sidewalls of respective openings 1166H. After liners 1167 are formed, a material (or materials) 1168 can be formed in openings 1166H over (e.g., formed on) liners 1167 to fill openings 1166H. The material of liners 1167 can be different from dielectric materials 1021 and 1022. Example materials for liners 1167 can include titanium nitride (TiN), carbon nitride (CN), or other materials. Material 1168 can be different from the material of liners 1167 and dielectric materials 1021 and 1022. Examples of material 1168 can include tungsten (W) or other materials. In alternative processes of forming memory device 1000, liners 1167 may be omitted (not formed in FIG. 11A), such that material 1168 can be formed after openings 1166H are formed. In such alternative processes, material 1168 (FIG. 11A) can directly contact dielectric materials 1021 and 1022 in openings 1166H.

The processes associated with FIG. 11A and FIG. 11B can include a performing a chemical mechanical polishing (CMP) process after structures 1165P and material 1145 are formed.

FIG. 12A and FIG. 12B show memory device 1000 after deck 542′ is formed over deck 541′. Forming deck 542′ can include forming additional levels of dielectric materials, which include dielectric materials (levels of dielectric materials) 1021 in respective levels 1001 of deck 542′, and dielectric materials (levels of dielectric materials) 1022 in respective levels 1002 in deck 542′.

Forming deck 542′ can include forming structures 1265P in a portion of dielectric materials 1021 and dielectric materials 1022 in region 454′ of deck 542′. Structures 1265P can be formed in ways similar to that of structures 1165P in deck 541′. For example, forming structures 1265P can include removing (e.g., etching) a portion of dielectric materials 1021 and 1022 in deck 542′ to form openings (e.g., holes) 1266H at the locations of structures 1265P. Then, liners 1267 can be formed on sidewalls of respective openings 1266H. After liners 1267 are formed, a material (or materials) 1268 can be formed in openings 1266H over (e.g., formed on) liners 1267 to fill openings 1266H. The materials for liners 1267 and material 1268 can be the same as the materials for liners 1167 and material 1168, respectively, of FIG. 11A. Forming deck 542′ in FIG. 12A and FIG. 12B can also include forming openings (e.g., holes) 1265H and openings (e.g., holes) 1244H.

Forming openings 1244H can include removing (e.g., etching) a portion of dielectric materials 1021 and 1022 in deck 542′ to form openings 1244H. As shown in FIG. 12A and FIG. 12B, openings 1244H can be formed in the locations in deck 542′ that are located over (e.g., vertically aligned with) material 1145 in openings 1144H (labeled in FIG. 11A and FIG. 11B).

Forming openings 1265H can include removing (e.g., etching) a portion of dielectric materials 1021 and 1022 in deck 542′ to form openings 1265H. As shown in FIG. 12A and FIG. 12B, openings 1265H can be formed such that they can be located over (e.g., vertically aligned with) respective structures 1165P. Openings 1244H and 1265H can be formed concurrently (e.g., formed in the same process step).

After openings 1244H and 1265H are formed, a material (or materials) 1245 can be formed in openings 1244H and 1265H. Material 1245 can be different from dielectric materials 1021 and 1022. Material 1245 can be the same as material (e.g., carbon) 1245 of FIG. 12A and FIG. 12B.

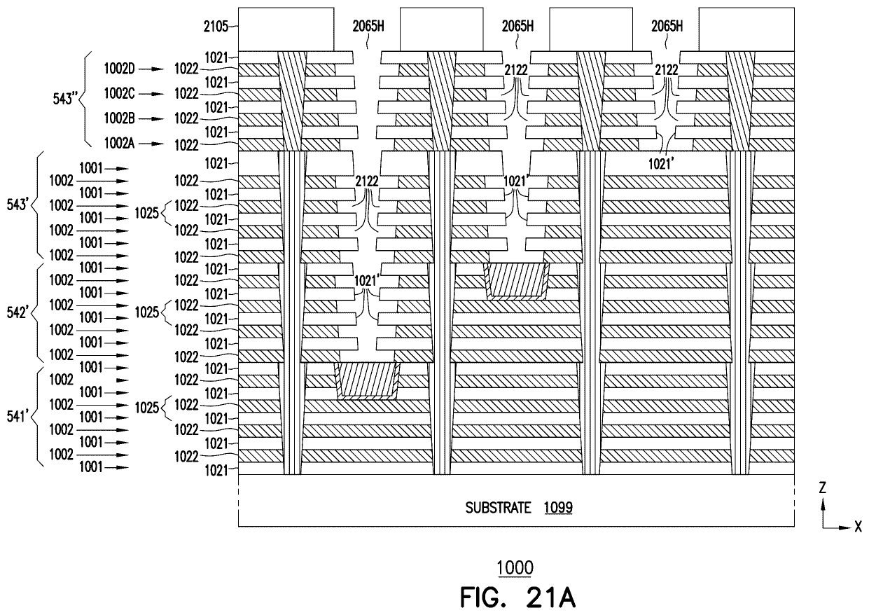

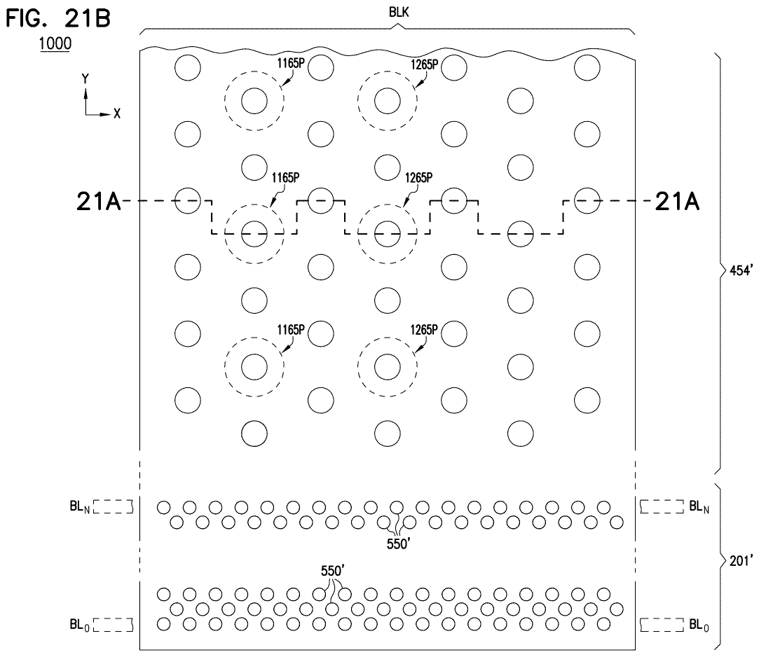

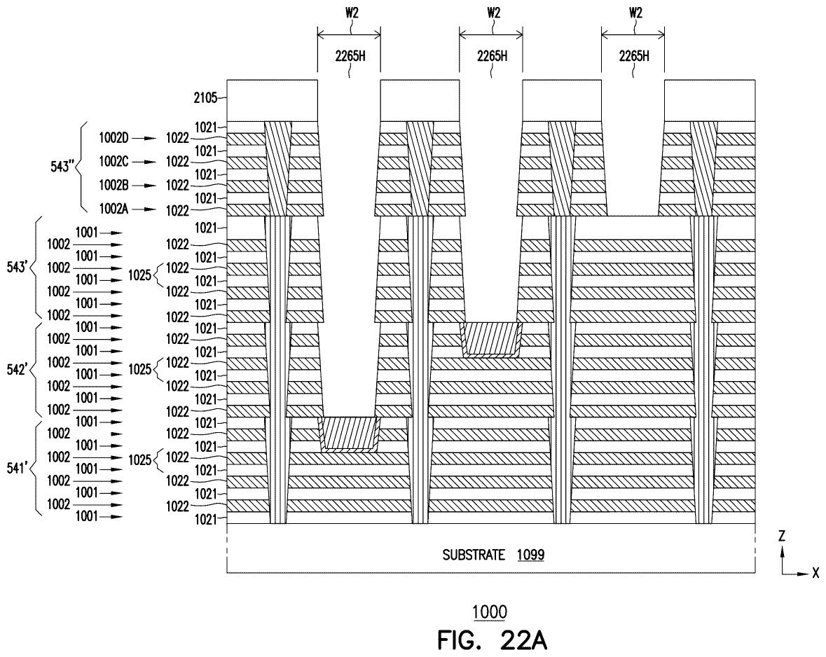

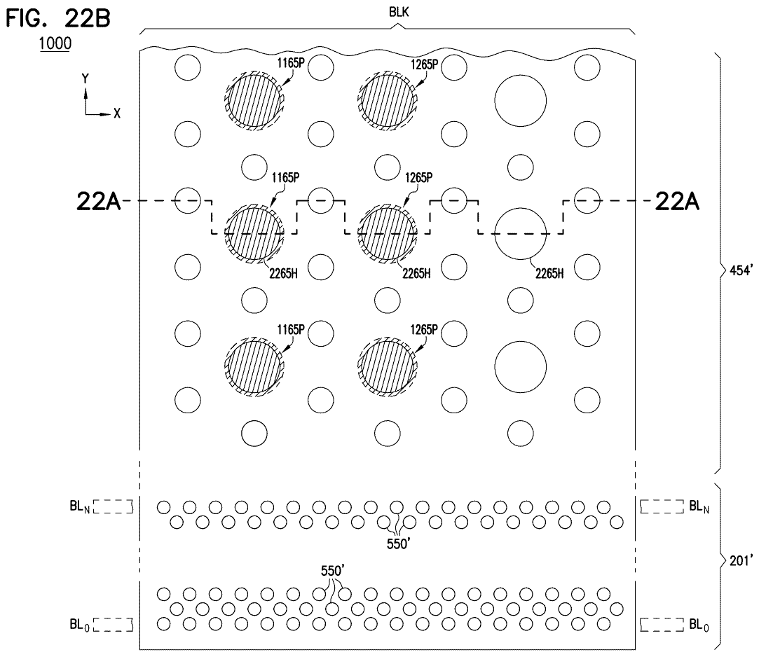

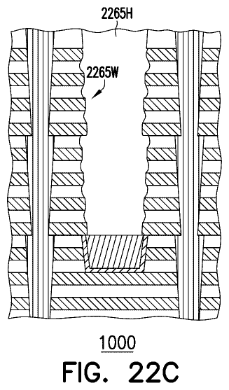

FIG. 12C and FIG. 12D show alternative openings 1265H_C and 1265H_D, respectively, associated with structure 1165P that can be substitute for opening 1265H of structure 1165P of FIG. 12A and FIG. 12B. As shown in FIG. 12C and FIG. 12D, unlike structure 1165P of FIG. 12A that is associated with a single opening 1265H, structure 1165P of FIG. 12C or FIG. 12D can be associated with a cluster of openings 1265H_C or a cluster of openings 1265H_D. Each of openings 1265H_C and 1265H_D can have a size (e.g., a diameter) that is different from (e.g., smaller than) the size (e.g., a diameter) of opening 1265H of FIG. 12A. In subsequent processes (e.g., FIG. 21A and FIG. 22A), cluster of openings 1265H_C or cluster of openings 1265H_D can be enlarged or merged together (e.g., etched) to form openings like openings 2265H (FIG. 22A).

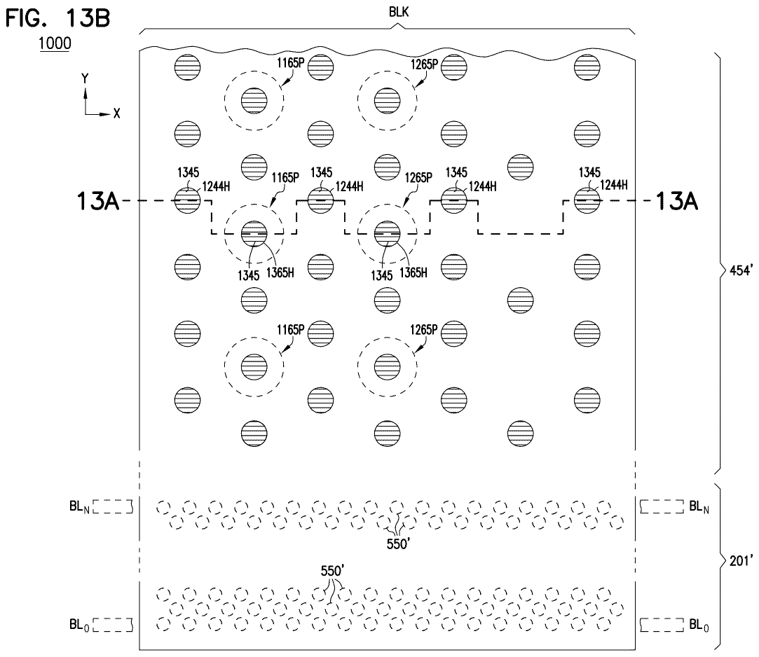

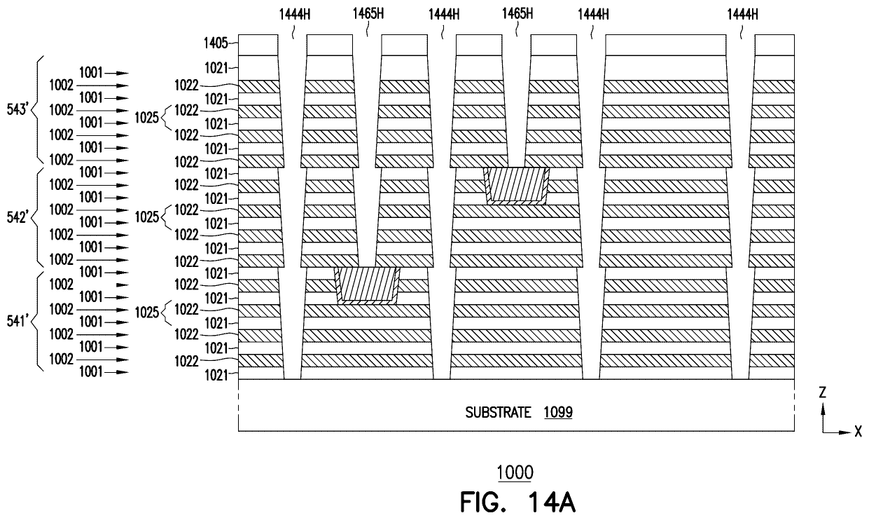

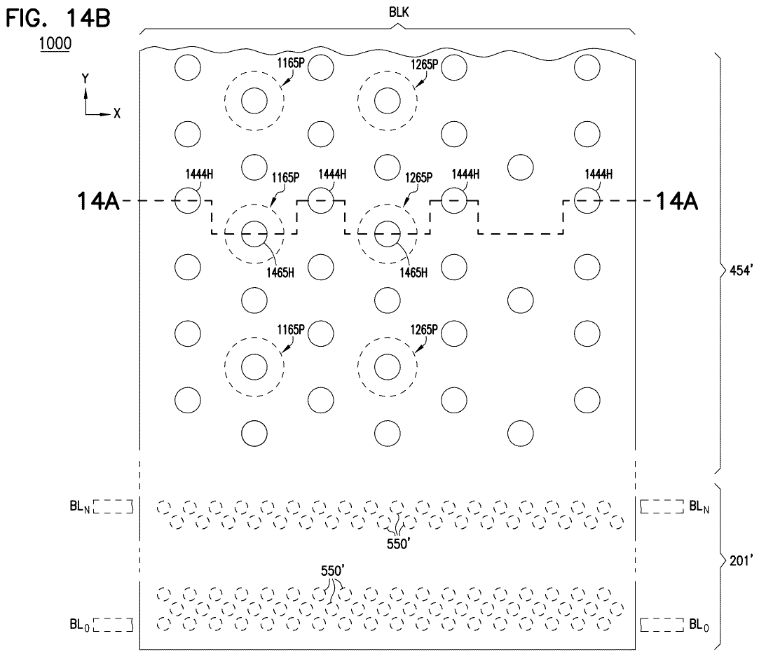

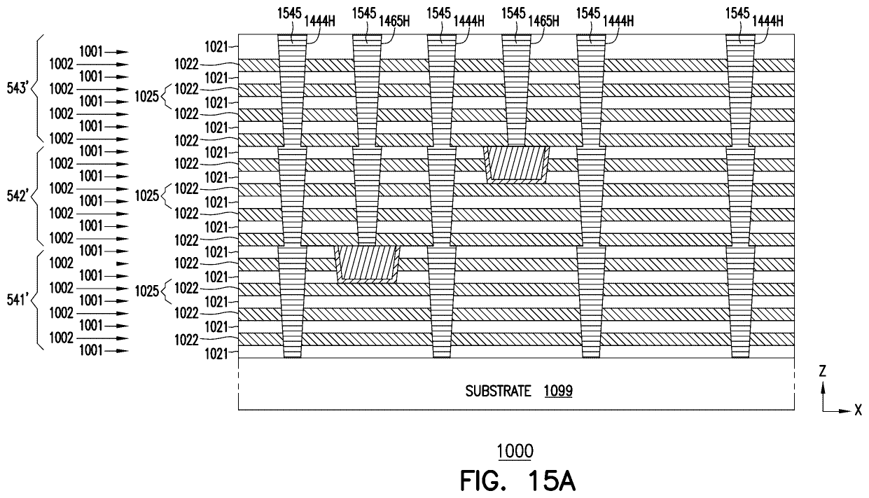

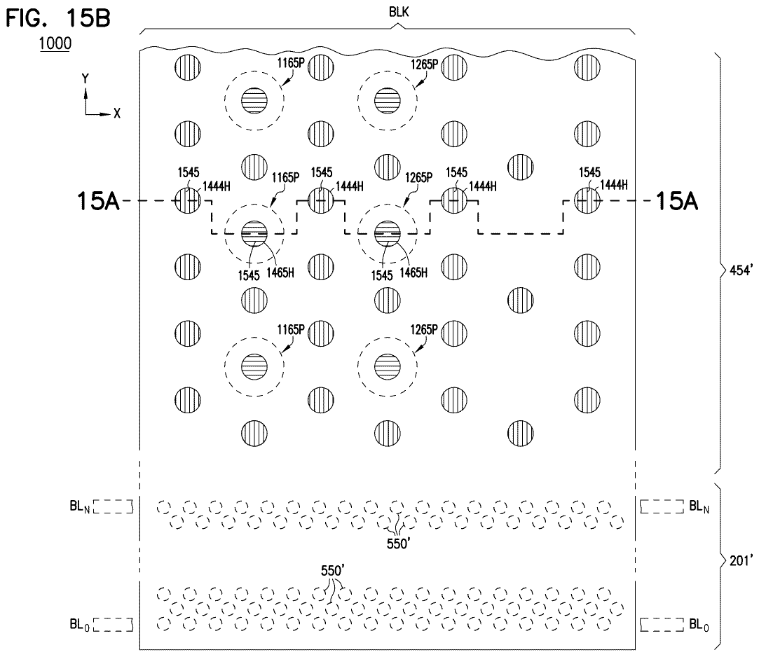

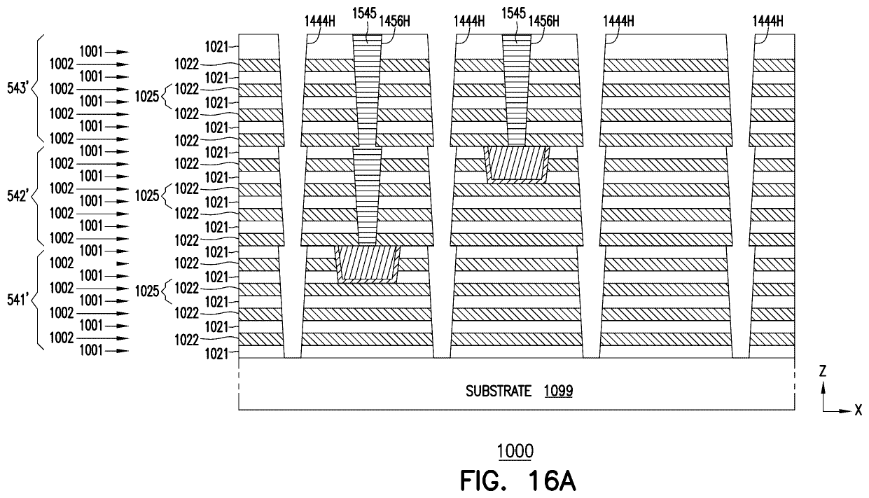

FIG. 12E shows another alternative opening 1265H_E associated with structure 1165P that can be substitute for opening 1265H of structure 1165P of FIG. 12A and FIG. 12B. As shown in FIG. 12E, like structure 1165P of FIG. 12A that is associated with a single opening 1265H, structure 1165P of FIG. 12E can also be associated with a single opening 1265H_E. However, opening 1265H_E can a size (e.g., a diameter) that is greater than the size (e.g., a diameter) of opening 1265H of FIG. 12A. For example, opening 1265H_E in FIG. 12E can have a size (e.g., a diameter) that is similar to the size (e.g., a diameter) of opening 2265H of FIG. 22A. The processes of forming memory device 200 can include forming opening 1265H_E and other openings (like opening 1365H in FIG. 13A) can avoid (e.g., skip) the processes of enlarging opening 1265H_E and other openings (like opening 1365H in FIG. 13A) because opening 1265H_E (and opening 1365H in FIG. 13A) can be formed with a size similar to (e.g., equal to) the size of opening 2265H of FIG. 22A.

The following description shows an example where opening 1265H (instead of openings 1265H_C, 1265H_D, or 1265H_E) is formed in FIG. 12A and FIG. 12B.

FIG. 13A and FIG. 13B show memory device 1000 after deck 543′ is formed over deck 542′. Forming deck 543′ can include forming additional levels of dielectric materials, which include dielectric materials (levels of dielectric materials) 1021 in respective levels 1001 of deck 543′, and dielectric materials (levels of dielectric materials) 1022 in respective levels 1002 in deck 543′. Forming deck 543′ can also include forming openings (e.g., holes) 1344H and openings (e.g., holes) 1365H.

Forming openings 1344H can include removing (e.g., etching) a portion of dielectric materials 1021 and 1022 in deck 543′ to form openings 1344H. As shown in FIG. 13A and FIG. 13B, openings 1344H can be formed in the locations in deck 543′ that are located over (e.g., vertically aligned with) material 1245 in openings 1244H (labeled in FIG. 12A and FIG. 12B).

Forming openings 1365H can include removing (e.g., etching) a portion of dielectric materials 1021 and 1022 in deck 543′ to form openings 1365H. As shown in FIG. 13A and FIG. 13B, a portion (e.g., a number) of openings 1365H can be formed such that they can be located over (e.g., vertically aligned with) material 1245 in openings 1265H (labeled in FIG. 12A and FIG. 12B). Another portion of openings 1365H can be formed such that they can be located over (e.g., vertically aligned with) respective structures 1665P. Openings 1344H and 1365H can be formed concurrently (e.g., formed in the same process step).

After openings 1344H and 1365H are formed, a material (or materials) 1345 can be formed in openings 1344H and 1365H. Material 1345 can be different from dielectric materials 1021 and 1022. Material 1345 can be the same as material (e.g., carbon) 1245 of FIG. 12A and FIG. 12B.

FIG. 14A and FIG. 14B show memory device 1000 after openings (e.g., holes) 1444H and 1465H are formed in respective decks 541′, 542′, and 543′. Forming openings 1444H and 1465H can include forming a pattern structure (e.g., a mask) 1405 over deck 543′. Pattern structure 1405 can include open spaces at the locations of openings 1444H and 1465H. The location of each opening 1444H can include the locations of respective openings 1144H, 1244H, and 1344H shown in FIG. 11A, FIG. 12A, and FIG. 13A, respectively. The location of each opening 1465H can include the locations of respective openings 1265H, and 1365H shown in FIG. 12A and FIG. 13A, respectively. Openings 1444H and 1465H can be formed concurrently (e.g., formed in the same process step).

Forming openings 1444H in FIG. 14A and FIG. 14B can include removing (e.g., exhuming) materials 1145, 1245, and 1345 from respective openings 1144H, 1244H, and 1344H (labeled in FIG. 11A, FIG. 12A, and FIG. 13A), respectively. Forming openings 1465H in FIG. 14A and FIG. 14B can include removing (e.g., exhuming) materials 1245 and 1345 from respective openings 1265H and 1365H (labeled in FIG. 12A, and FIG. 13A).

As shown in FIG. 14A, structures 1165P and 1265P (labeled in FIG. 11A and FIG. 12A, respectively) associated with respective openings 1166H can remain (not to be removed) in the processes associated with FIG. 14A and FIG. 14B.

FIG. 15A and FIG. 15B show memory device 1000 after a material (or materials) 1545 is formed (e.g., filled) in openings 1444H and 1465H, and after structure 1405 is removed. Material 1145 can be different from dielectric materials 1021 and 1022. An example of material 1245 can include carbon or other materials. Material 1545 can be a sacrificial material that will be removed in subsequent processes. The processes associated with FIG. 21 can include a CMP process after material 1545 formed.

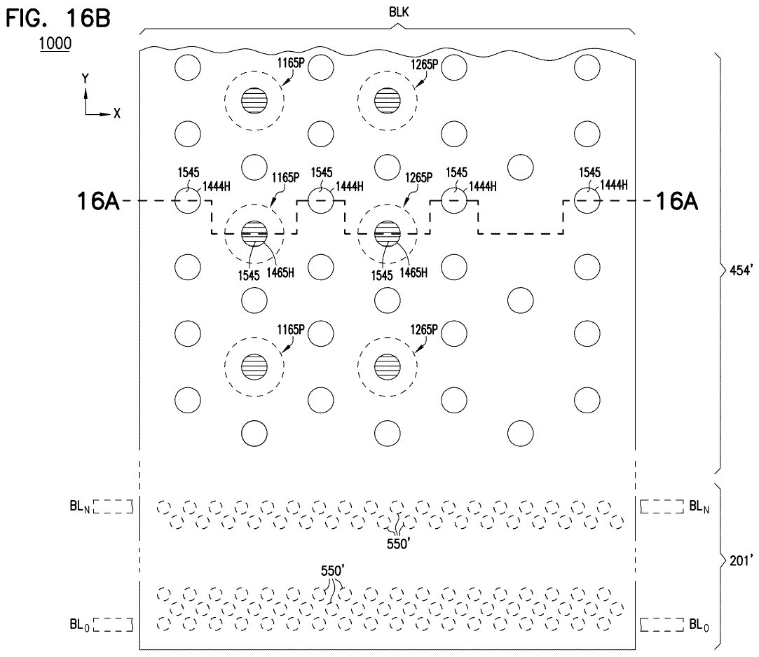

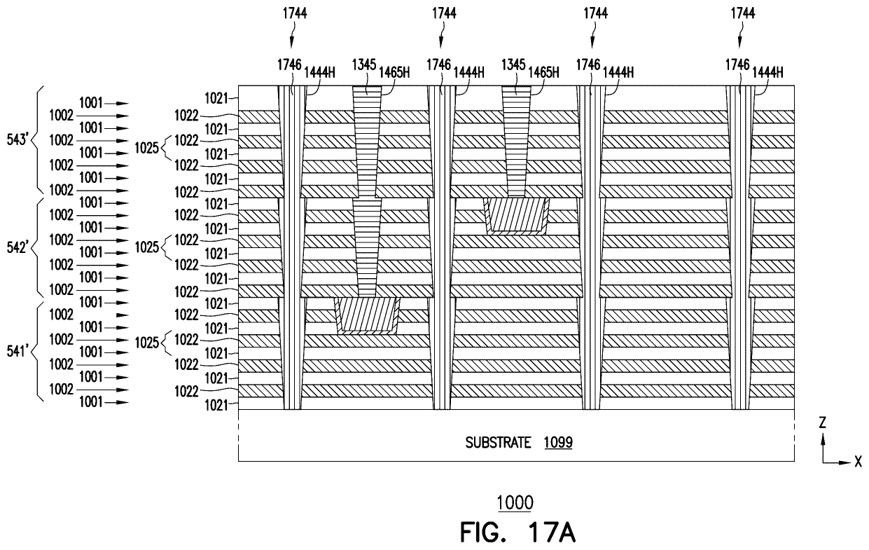

FIG. 16A and FIG. 16B show memory device 1000 after material 1545 is removed (e.g., exhumed) from openings 1444H. Material 1545 in structures 1165 and 1265 can remain.

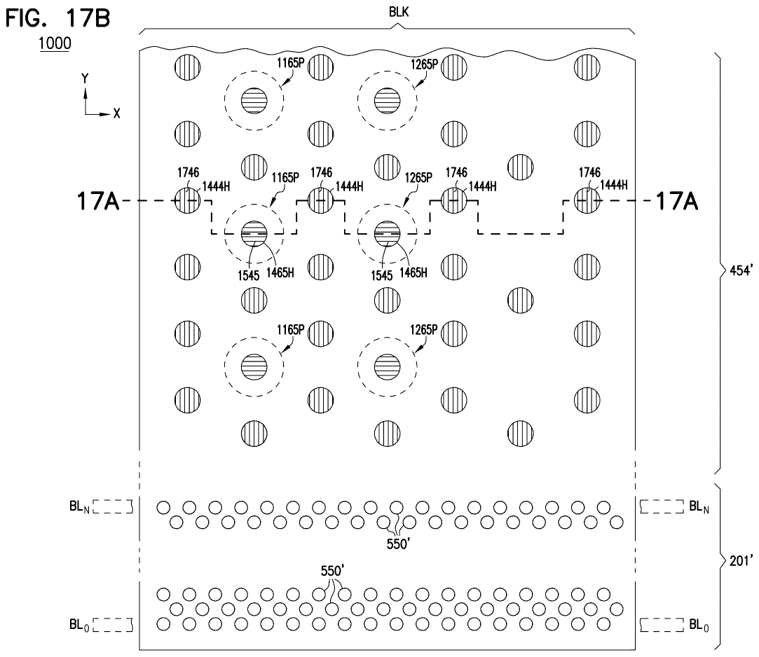

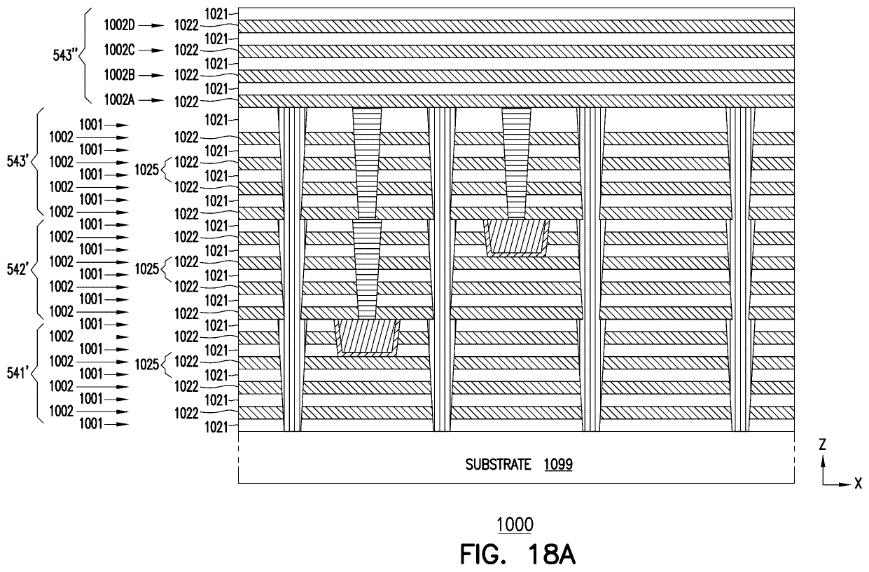

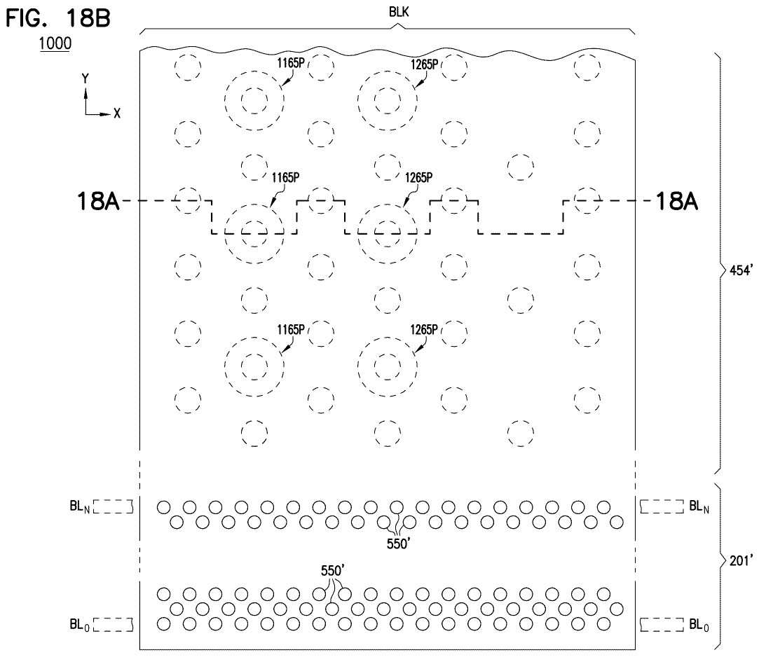

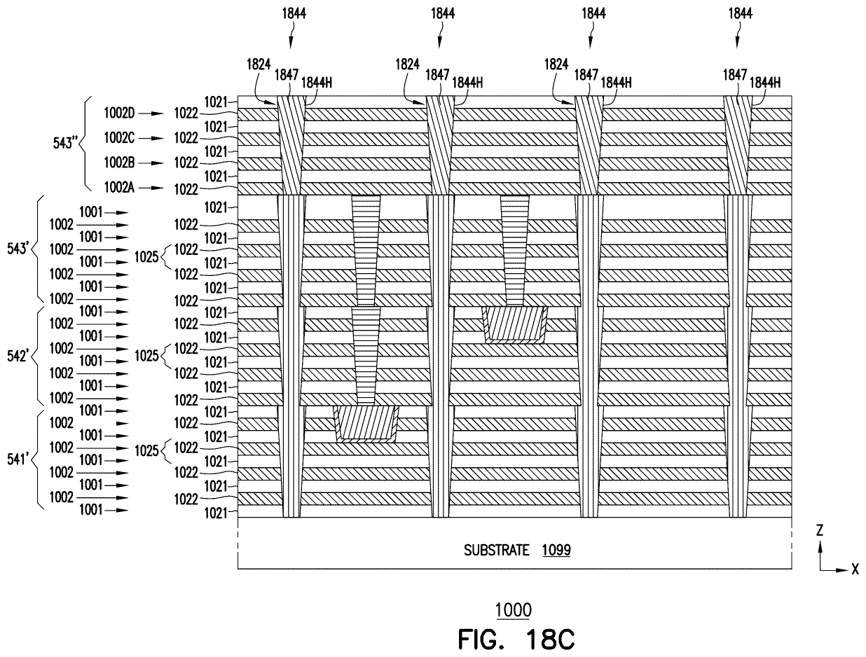

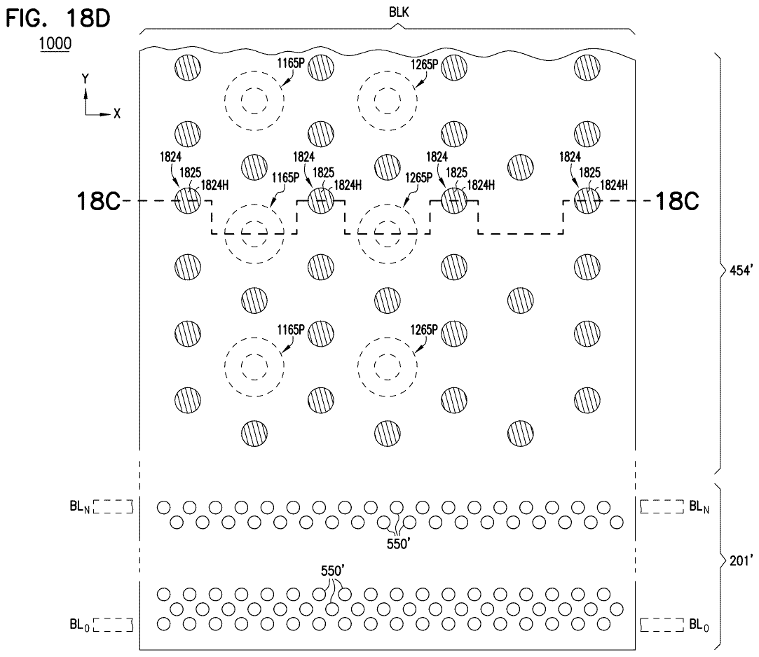

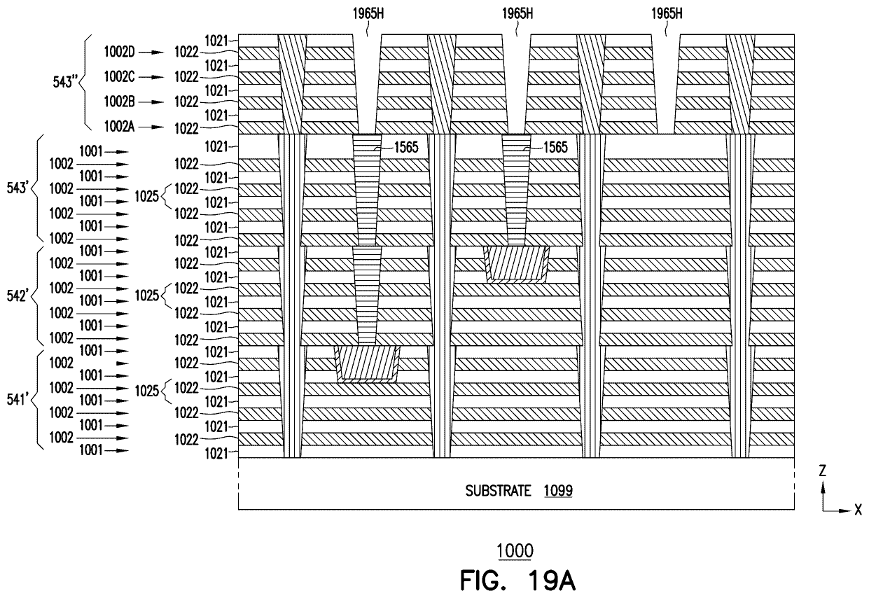

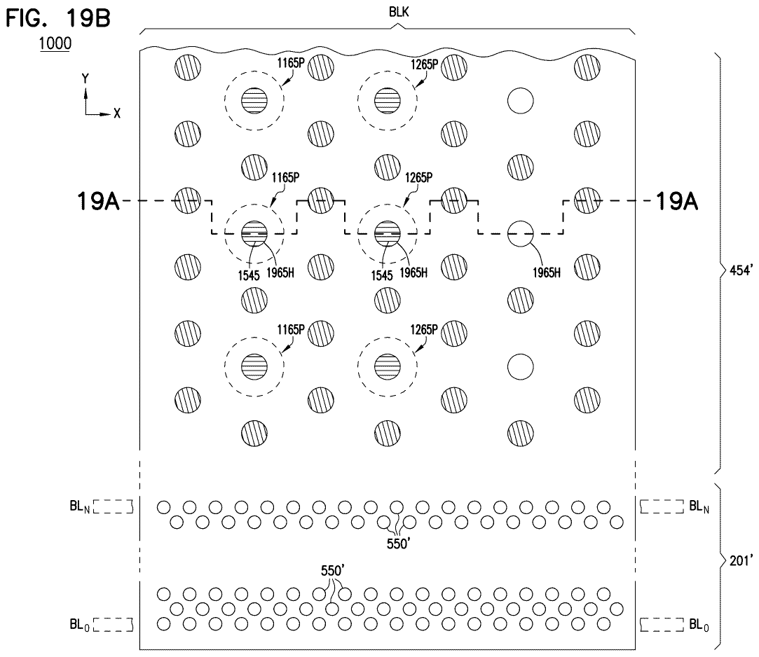

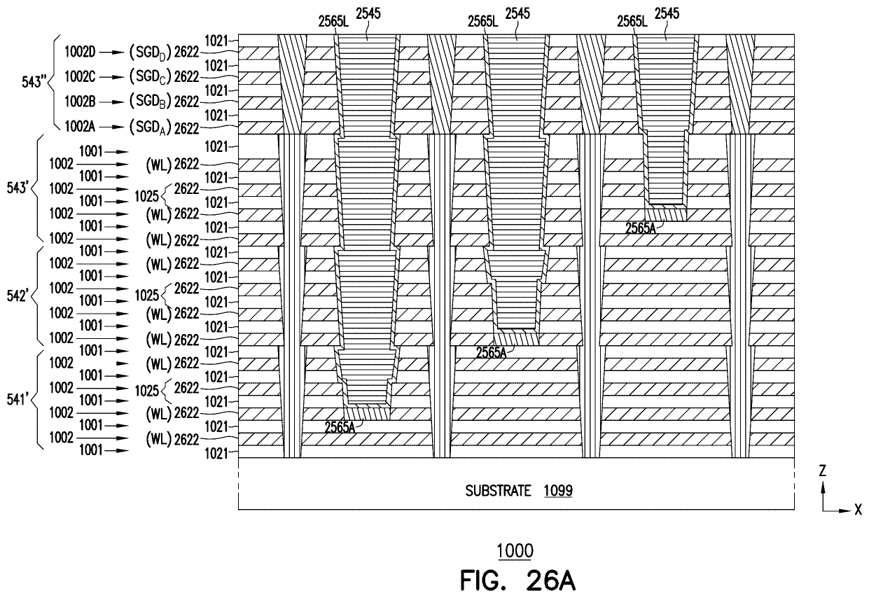

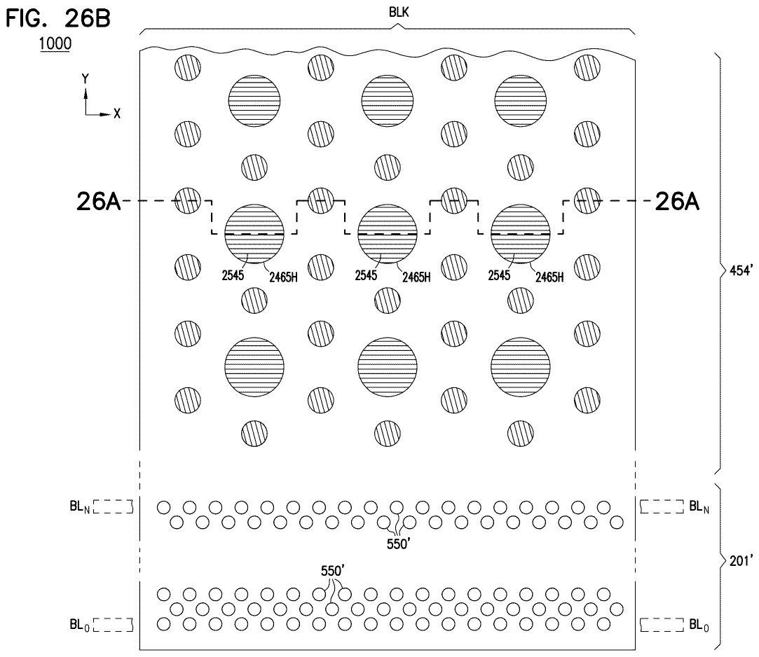

FIG. 17A and FIG. 17B show memory device 1000 after pillars (dielectric pillars) 1744 are formed. Forming pillars 1744 can include forming (e.g., filling) a material (or materials) 1746 in openings 1444H. Pillars 1744 are electrically separated from (electrically uncoupled to) the control gates of memory device 1000 that are subsequently formed (FIG. 26A) on respective levels 1002. Pillars 1744 can be formed to provide structural support to a portion (e.g., region 454′) of decks 541′, 542′, and 543′ of memory device 1000. The processes associated with FIG. 17A and FIG. 17B can include forming pillars (memory cell pillars) 550′ in region (memory array region) 201′. As mentioned above, the description here omits detailed processes of forming pillars 550′. In FIG. 17A and FIG. 17B, pillars 1744 and pillars 550′ can be formed concurrently. Thus, in an example, material 1746 of pillars 1744 can be similar to or the same as the materials of pillars 550′.

FIG. 18A and FIG. 18B show memory device 1000 after structure 543″ is formed. Structure 543″ can be considered part of a top deck (e.g., deck 543′) of memory device 1000. Forming structure 543″ can include forming additional levels of dielectric materials (e.g., silicon dioxide) 1021, and forming dielectric materials (e.g., silicon nitride) 1022 on respective levels 1002A, 1002B, 1002C, and 1002D. As shown in FIG. 18A, dielectric materials 1022 on respective levels 1002A, 1002B, 1002C, that are interleaved with the levels (not labeled) of dielectric materials 1021 in structure 543″.

FIG. 18C and FIG. 18D show memory device 1000 after pillars (dielectric pillars) 1824 are formed in structure 543″. Forming pillars 1824 can include removing (e.g., etching) a portion of dielectric materials 1021 and 1022 in structure 543″ to form openings 1824H. As shown in FIG. 18B and FIG. 18C, openings 1824H can be formed in the locations in structure 543″ that are located over (e.g., vertically aligned with) pillars 1744 (labeled in FIG. 17A). After openings 1824H are formed, a material (or materials) 1847 can be formed in openings 1824H. Material 1847 can include a dielectric material, a semiconductor material, a conductive material, or any combination of a dielectric material, a semiconductor material, and a conductive material. As shown in FIG. 18C, pillars 1824 can be located over (e.g., vertically aligned with) pillars 1744. Pillars 1824 are electrically separated from (electrically uncoupled to) the select lines (e.g., drain select lines) of memory device 1000 that are subsequently formed (FIG. 26A) on respective levels 1002A, 1002B, 100C, and 1002C. As shown in FIG. 18C, memory device 1000 can include dielectric pillars 1844. Each dielectric pillar 1844 can include a combination of a pillar 1824 (FIG. 18A) and a pillar 1744 (labeled in FIG. 17A). Dielectric pillars 1844 can be similar to dielectric pillars 644 of memory device 200 (FIG. 6 and FIG. 7).

In an alternative process of forming memory device 1000, forming structure 543″ may be omitted (not to performed), such that some of dielectric materials 1021 and 1022 of deck 543′ (e.g., dielectric materials 1021 and 1022 in the top portion of deck 543′) can be used for dielectric materials 1021 and 1022 of structure 543″.

FIG. 19A and FIG. 19B show memory device 1000 after openings (e.g., holes) 1965H are formed in structure 543″. Forming openings 1965H can include removing a portion of dielectric materials 1021 and 1022 in structure 543″ to expose material 1545 in respective structures 1165P and 1265P. As shown in FIG. 19A and FIG. 19B, some of openings 1965H also expose part of (e.g., dielectric material 1021) of deck 543′.

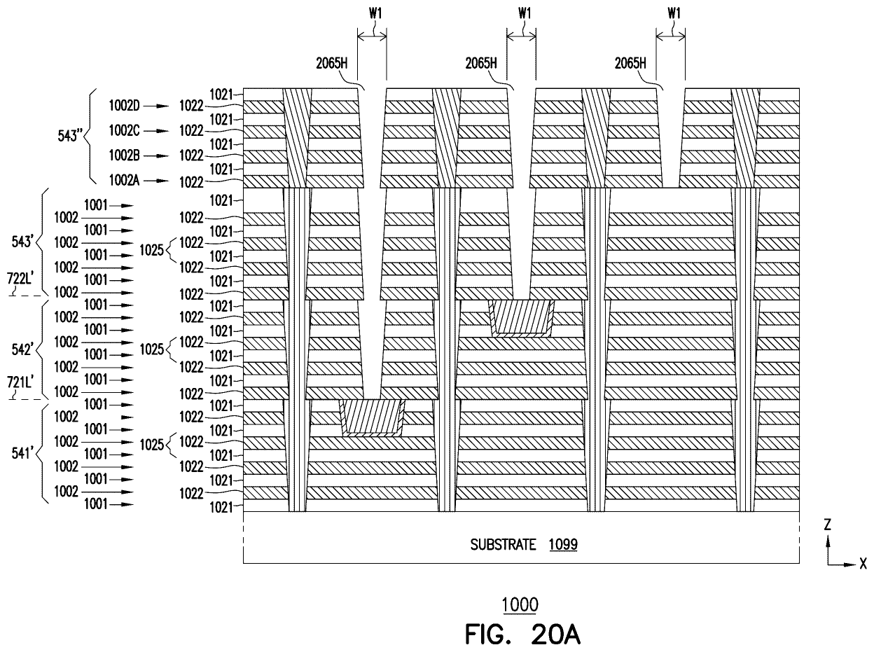

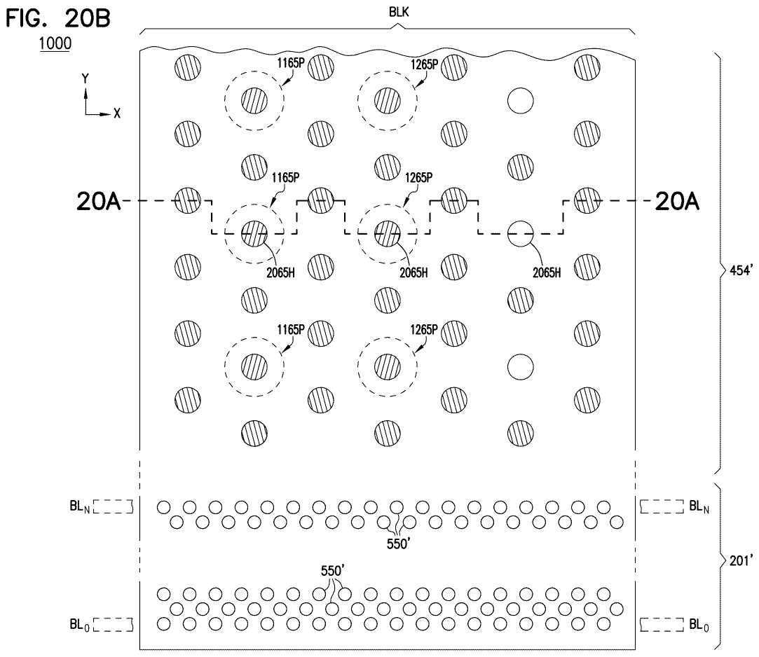

FIG. 20A and FIG. 20B show memory device 1000 after materials 1245 and 1545 over respective over structures 1165 and 1265 are removed (e.g., exhumed), thereby forming openings 2065H over structures 1165 and 1265. Openings 2065H located over structures 1165 and 1265 can include (or can be part of) openings 1965H over structures 1165 and 1265 of FIG. 19A and FIG. 19B. As shown in FIG. 20A, openings 2065H can have a width (e.g., diameter) W1. In subsequent processes, openings 2065H can be enlarged (in the X-Y direction), such that width W1 can be increased to a greater width (e.g., width W2 in FIG. 22A).

FIG. 21A and FIG. 21B show memory device 1000 after dielectric materials (e.g., silicon nitride) 1022 at location 2122 that were exposed at openings 2165H are removed (e.g., etched). For simplicity, only a few of locations 2122 are labeled. The processes associated with FIG. 21A and FIG. 21B can include forming a pattern structure 2105 over structure 543″. Pattern structure 2105 can include open spaces at the locations of openings 2165H to allow removal of dielectric materials 1022 exposed at openings 2165H. FIG. 21A and FIG. 21B also show portions 1021′ of dielectric materials 1021 exposed at opening 2065H. For simplicity, only a few of portions 1021′ are labeled.

FIG. 22A and FIG. 22B show memory device 1000 after portion 1021′ (labeled in FIG. 21A) of dielectric materials (e.g., silicon dioxide) 1021 that were exposed at openings 2065H are removed (e.g., etched). As shown in FIG. 22A and FIG. 22B, openings 2265H are formed at respective locations of openings 2065H (FIG. 20A and FIG. 20B). As shown in FIG. 22A, openings 2265H can have a width (e.g., diameter) W2, which is greater than width W1 of openings 2065H of FIG. 20A. FIG. 22C shows more details of a portion of memory device 100 of FIG. 21A including a sidewall 2265W of a respective opening 2265H. As shown in FIG. 22C, sidewall 2265W can have wavy profiled formed by portions of dielectric materials 1021 and 1022 at openings 2265H.

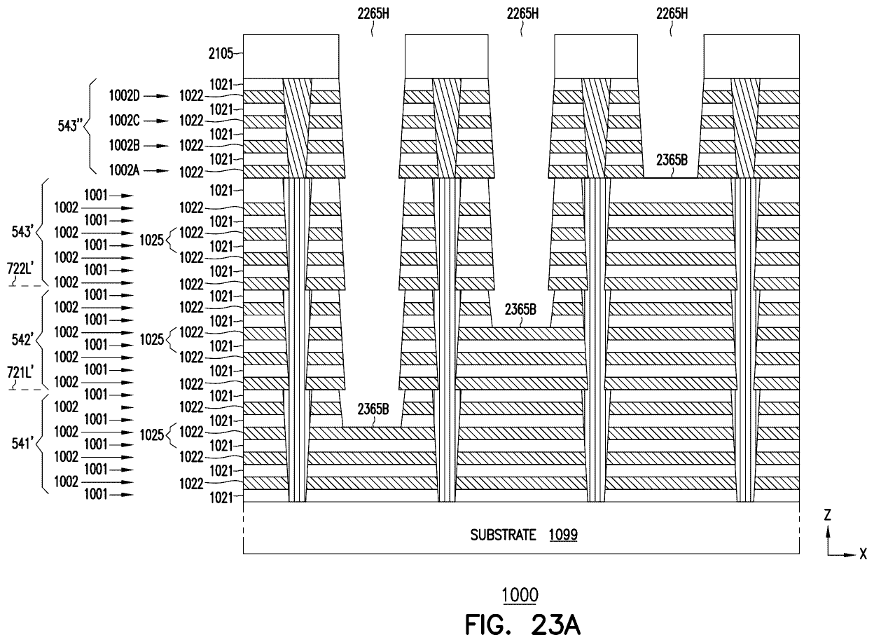

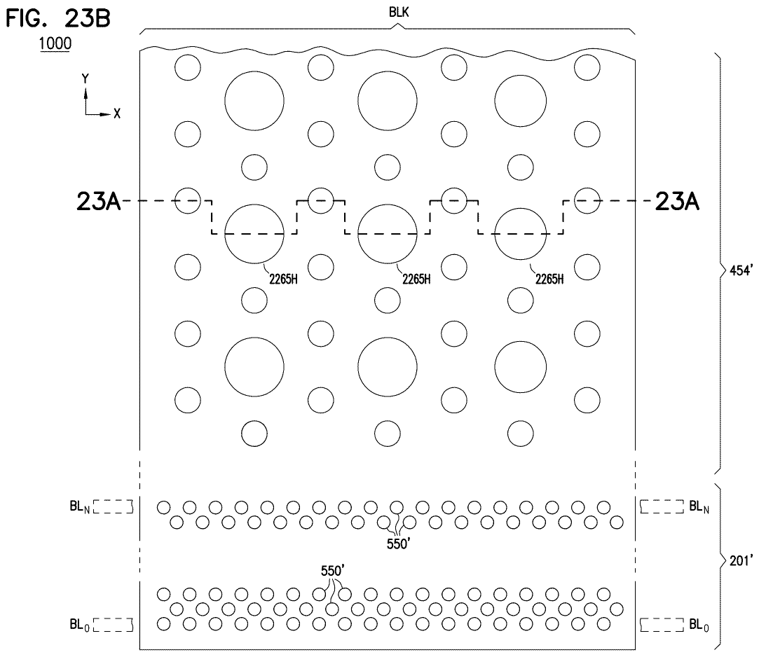

FIG. 23A and FIG. 23B show memory device 1000 after structures 1165P and 1265P are removed (e.g., exhumed). As shown in FIG. 23A, openings 2265H can have respective bottoms 2365B.

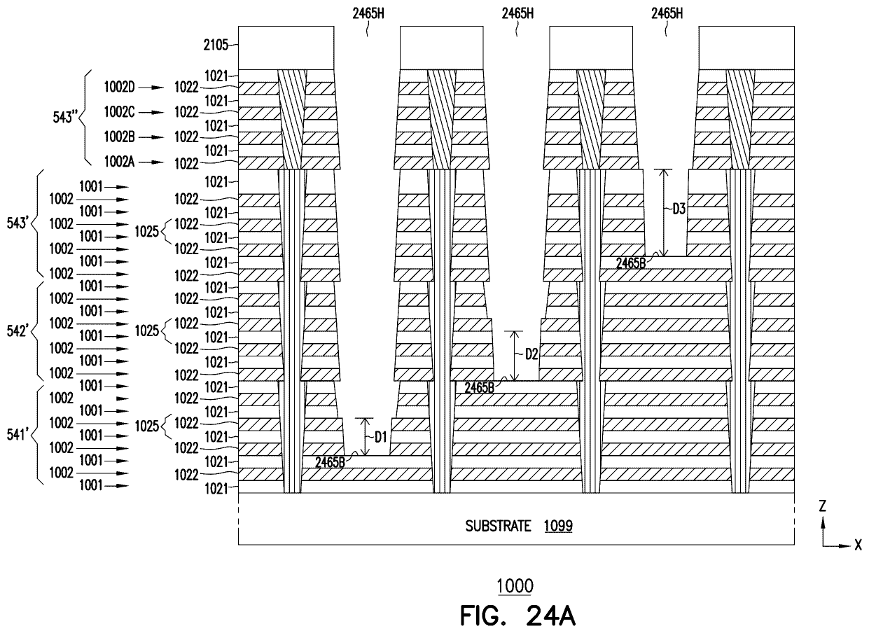

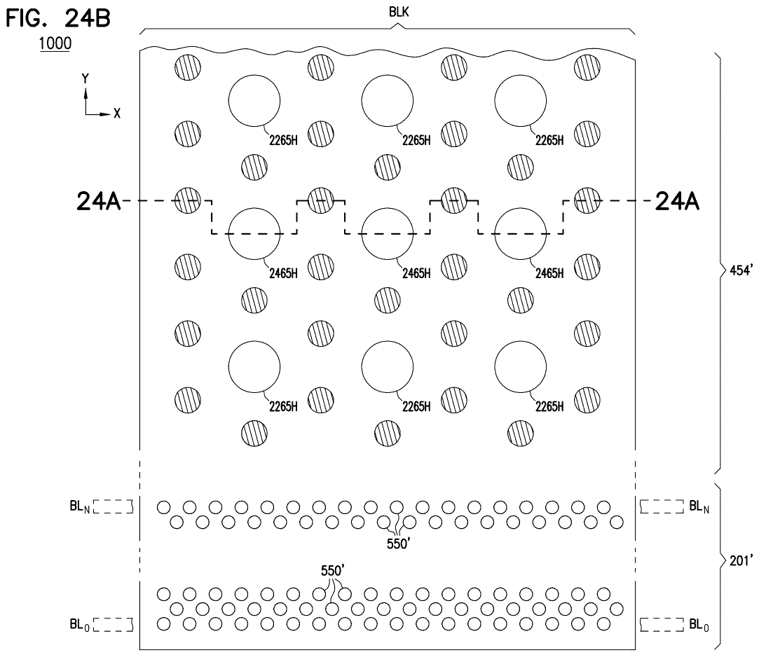

FIG. 24A and FIG. 24B show memory device 1000 after openings 2465H are formed. Forming openings 2465H can include increasing the depths (in the Z-direction) of openings 2265H in FIG. 23A by respective distances (dimensions) D1, D2, and D3 from previous depths shown in FIG. 23A. Increasing the depths of openings 2265H can include removing portions of dielectric materials 1021 and 1022 that are directly under bottoms 2365B of openings 2265H (FIG. 23A). As shown in FIG. 24A, openings 2465H can have respective bottoms 2465B over respective levels of dielectric materials 1021. Bottoms 2465B can be adjacent respective target locations (corresponding to levels 1002) of the control gates (FIG. 29A) that are subsequently formed.

The side view of memory device 100 in FIG. 24A shows three openings 2465H having three different depths. However, other openings 2465H (FIG. 24B) can have depths different from the depths shown in FIG. 24A corresponding to the target locations (corresponding to levels 1002) of the control gates (FIG. 29A) that are subsequently formed. For example, nine openings 2465H in FIG. 24B (top view) can have nine respective depths (and nine corresponding bottoms 2465B) at different levels (nine different levels) among levels 1002 (FIG. 24A). This allows the conductive contacts (e.g., word line contacts), which are subsequently formed in openings 2465H (FIG. 29A), of memory device 1000 can contact respective control gates (FIG. 26A) formed on respective levels 1002 (FIG. 26A).

As shown in FIG. 24A, since dielectric materials 1021 and 1022 in openings 2265H in FIG. 23A are already removed, dielectric materials 1021 and 1022 under bottom 2365B of the same opening 2265H from only one deck (e.g., deck 541′, 542′, or 543′) may be removed to access target locations (corresponding to levels 1002) of the control gates (FIG. 29A) that are subsequently formed. Improvement and benefits of the processes described herein (e.g., formation of structures 1165P and 1265P and formation of the described conductive contacts (e.g., conductive contacts 2965_{WL} in FIG. 29A) include improved reliability and performance, and cost reduction, as further discussed below.

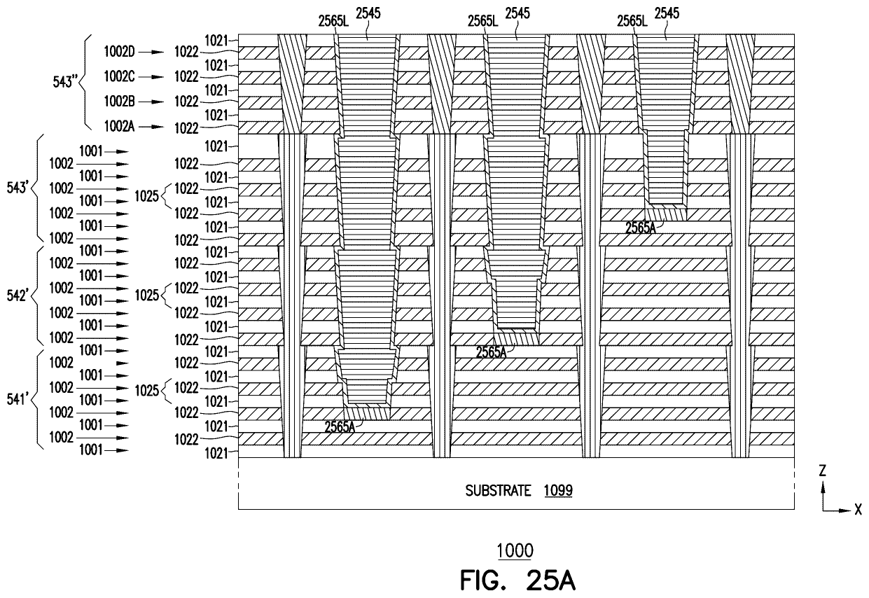

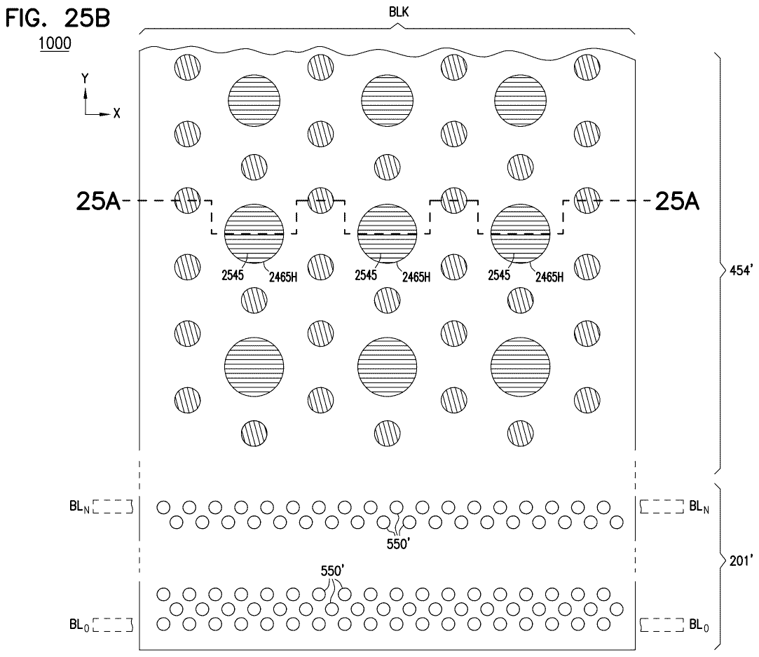

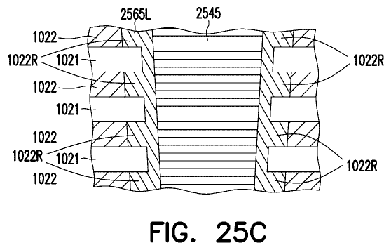

FIG. 25A and FIG. 25B show memory device 1000 after formation of structures 2565A, liners (dielectric liners) 2565L, materials (e.g., sacrificial materials) 2545 in respective openings 2465H. FIG. 25C shows an enlarged portion of memory device 1000 of FIG. 25A. In FIG. 25A and FIG. 25B, structures 2565A, liners 2565L, and materials 2545 can be sequentially formed. For example, the processes associated with FIG. 25A and FIG. 25B can include forming structures 2565A in openings 2465H, forming liners 2565L after structures 2565A, and forming (e.g., filling) materials 2545 in openings 2465H after liners 2565L are formed. Structure 2565A can be formed from a material (or materials) that is different from dielectric materials 1022. Structures 2565A can include aluminum oxide, metal, or other materials. In an example, structure 2565A can be formed by a doping the material at the location of structure 2565A with an impurity (e.g., carbon or other materials) via implant, thermal treatment, or both. In an example, material 2545 can include carbon or other materials. Liners 2565L can include silicon dioxide or other dielectric materials. The processes associated with FIG. 25A and FIG. 25B can also include removing pattern structure 2105 and performing a CMP process.

As shown in FIG. 25C, memory device 1000 can include recesses 1022R. Recesses 1022R can be formed by removing respective portions of dielectric materials (e.g., silicon nitride) 1022 that are exposed at openings 2465H (FIG. 24A). Then, in the processes associated with FIG. 25A, the material (e.g., silicon dioxide) of liner 2565L can also be formed (e.g., filled) in recesses 1022R, as shown in FIG. 25C.

FIG. 26A and FIG. 26B show memory device 1000 after conductive materials (levels of conductive materials) 2622 are formed. Forming conductive materials 2622 can include removing dielectric materials 1022 in FIG. 25A from respective levels 1002, and forming conductive materials 2622 (FIG. 26A) in levels 1002 at the locations of dielectric materials 1022 that were removed. Conductive materials 2622 can be similar to (or the same as) conductive materials 522 of memory device 200 (FIG. 5A and FIG. 7).

As shown in FIG. 26A and FIG. 26B, the conductive materials 2622 on levels 1002 can form respective control gates on levels 1002 associated with signals WL of memory device 1000. The control gates associated with signals WL can be similar to the control gates associated with signal WL of memory device 200 of FIG. 5A and FIG. 7.

In FIG. 26A and FIG. 26B, conductive materials 2622 on levels 1002A, 1002B, 1002C, and 1002D can form select lines (e.g., four select lines) associated with signals SGD_{A}, SGD_{B}, SGD_{C}, and SGD_{D} of memory device 1000. The select lines associated with signals SGD_{A}, SGD_{B}, SGD_{C}, and SGD_{D} can be similar to select lines 280_{A}, 280_{B}, 280_{C}, and 280_{D} associated with respective signals SGD_{A}, SGD_{B}, SGD_{C}, and SGD_{D} of memory device 200 in FIG. 3B and FIG. 5B.

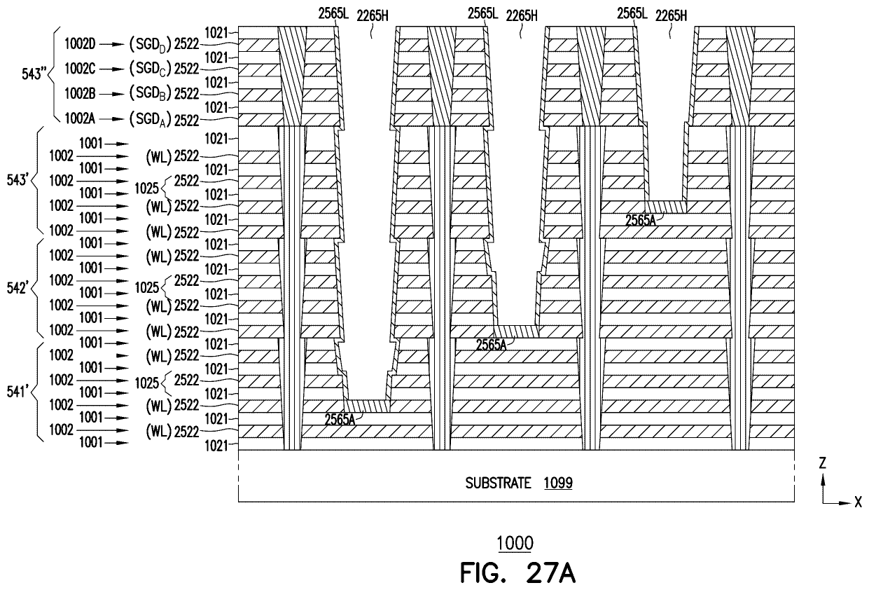

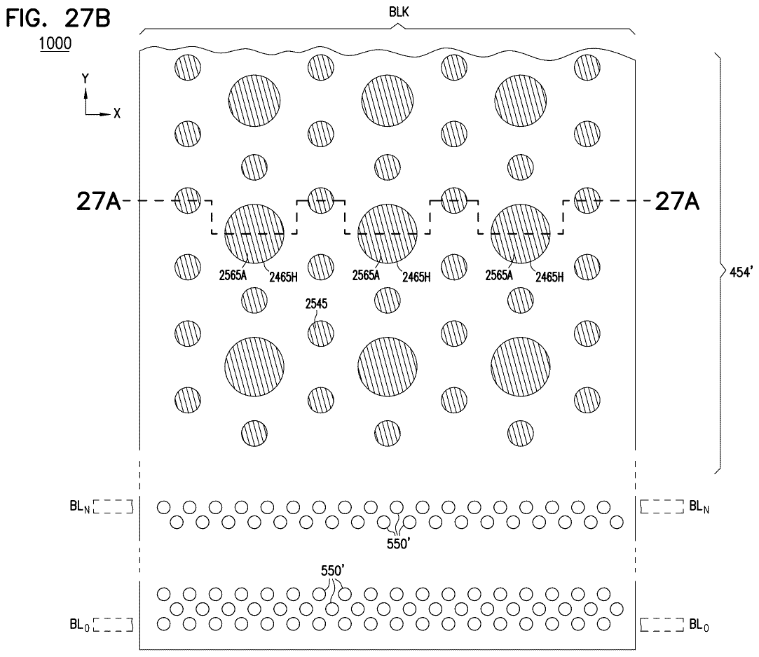

FIG. 27A and FIG. 27B show memory device 1000 after material 2545 in FIG. 26A is removed (e.g., exhumed) from openings 2465H. As shown in FIG. 27A, a portion (e.g., bottom portion) of liner 2565L in each of openings 2465H is also removed (e.g., punched). As shown in FIG. 27A, structure 2565A is exposed at respective openings 2465H.

FIG. 28A and FIG. 28B show memory device 1000 after the structures 2565A are removed (e.g., exhumed) from openings 2465H.

FIG. 29A and FIG. 29B show memory device 1000 after conductive contacts 2965_{WL}, including conductive pads 2965C, are formed. Forming conductive contacts 2965_{WL} can including forming (e.g., filling) conductive materials 2965M in openings 2465H (labeled in FIG. 28A). Conductive materials 2965M can be the same as (or alternatively different from) conductive materials 2622 that form the control gates of memory device 1000. Conductive contacts 2965_{WL} can be similar to conductive contacts 665_{WL} of FIG. 7.

As shown in FIG. 29A, memory device 1000 can include level 721L′ between decks 541′ and 542′ and level 722L′ between decks 542′ and 543′. Levels 721L′ and 722L′ are similar to levels 721L and 722L, respectively, of memory device 200 of FIG. 5A and FIG. 7.

As shown in FIG. 29A, conductive contacts 2965_{WL} can have a segmented profile like some of conductive contacts 2965_{WL} memory device 200 of FIG. 7. For example, conductive contacts 2965_{WL} of memory device 1000 can include respective regions 665R′ and protrusions 665X′ at respective levels 721L′ and 722L′. Regions 665R′ and protrusions 665X′ have similar structures as regions 665R and protrusions 665X of memory device 200 shown in FIG. 8A and described above with reference to FIG. 8A. Thus, for simplicity detailed descriptions of regions 665R′ and protrusions 665X′ of memory device 1000 are omitted. In alternative structures of memory device 1000, conductive contacts 2965_{WL} can have regions 665R′ and protrusions 665X′ can have similar structures like conductive contacts 665_{WL} shown in FIG. 8C and FIG. 8D.

FIG. 29A shows a side view of memory device in the X-Z direction. Different side views in the Y-Z direction of memory device 1000 along line 29C/29D are shown in FIG. 29C and FIG. 29D.

FIG. 29C shows a side view of memory device 1000 along line 29C/29D of FIG. 29A. For simplicity, FIG. 29C omits the portion of memory device 1000 that include structure 543″ (FIG. 29A) and the portion of memory device 1000 between pillar (memory cell pillar) 550′ and conductive contacts 2965_{WL} (e.g., word line contacts) of decks 541′, 542′, and 543′.

As shown in FIG. 29C, pillar 550′ can include a structure 730′ and a dielectric material 705′ that are similar to structure 730 and a dielectric material 705, respectively, of memory device 200 shown in FIG. 7. Thus, for simplicity detailed descriptions of structure 730′ and a dielectric material 705′ of memory device 1000 are omitted. Protrusions 665X′ of memory device 1000 in FIG. 29C correspond to some of protrusions 665X′ of memory device 1000 in FIG. 29A.

FIG. 29D shows a side view of memory device 1000 along line 29C/29D of FIG. 29A. For simplicity, FIG. 29A omits the portion of memory device 1000 that include decks 541′ and 542′ and part of deck 543′.

As shown in FIG. 29D, structure 543″ can include conductive contacts (e.g., drain select line contacts) 2965_{SGD.A}, 2965_{SGD.B}, 2965_{SGD.C}, and 2965_{SGD.D} coupled to the select lines (e.g., drain select lines) associated with signals SGD_{A}, SGD_{B}, SGD_{C}, and SGD_{D}. As mentioned above, the select lines associated with signals SGD_{A}, SGD_{B}, SGD_{C}, and SGD_{D} of memory device 1000 can be similar to select lines 280_{A}, 280_{B}, 280_{C}, and 280_{D} associated with respective signals SGD_{A}, SGD_{B}, SGD_{C}, and SGD_{D} of memory device 200 in FIG. 3B and FIG. 5B.

The conductive material of conductive contacts 2965_{SGD.A}, 2965_{SGD.B}, 2965_{SGD.C}, and 2965_{SGD.D} can be similar to (or the same as) conductive material 2965M of conductive contacts 2965_{WL}. Conductive contacts 2965_{SGD.A}, 2965_{SGD.B}, 2965_{SGD.C}, and 2965_{SGD.D} can be formed concurrently with conductive contacts 2965_{WL}.

The processes of forming memory device 1000 described above with reference to FIG. 10A through FIG. 29D can include other processes to form a complete memory device (e.g., memory device 1000). Such processes are omitted from the above description so as not to obscure the subject matter described herein. Further, the processes of forming memory device 1000 described above with reference to FIG. 10A through FIG. 29D forms three decks (e.g., decks 541′, 542′, and 543′) of memory device 1000 as an example. However, the processes of forming memory device 1000 described above with reference to FIG. 10A through FIG. 29D can be used to form memory device 1000 that include fewer than three or more than three decks.

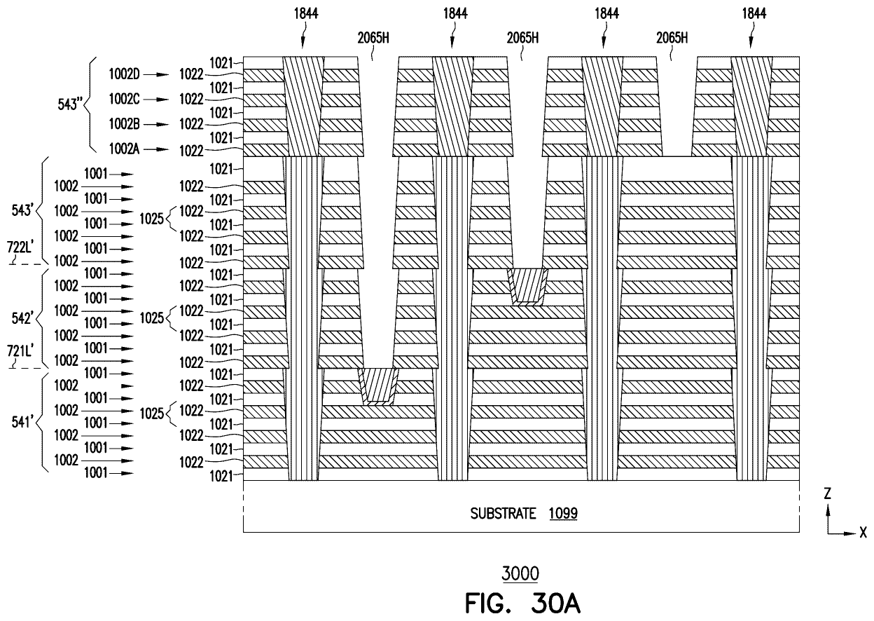

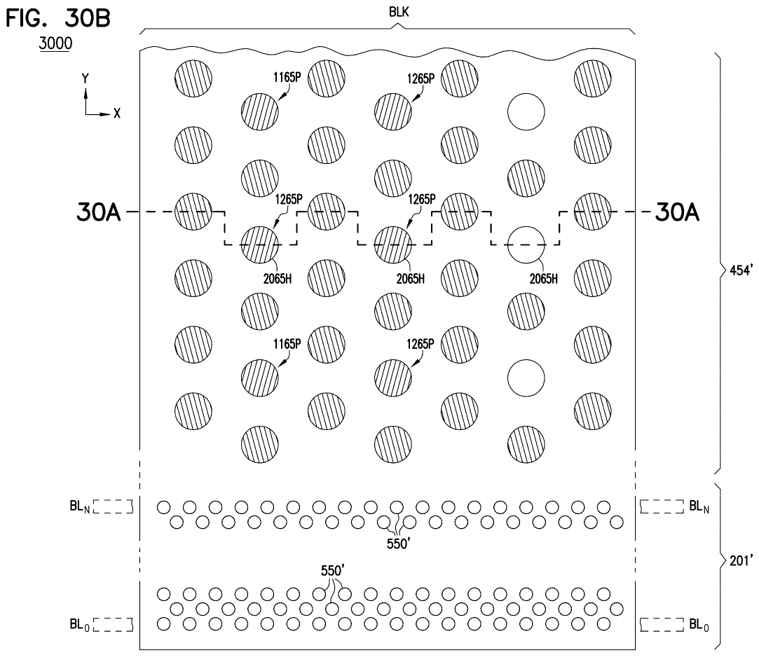

FIG. 30A through FIG. 33D show different views of elements during processes of forming a memory device 3000, according to some embodiments described herein. Some of the processes and materials used in forming memory device 3000 are similar to or the same as the processes of forming memory device 1000. Thus, for simplicity, similar or the same elements between memory device 1000 (FIG. 10A through FIG. 29D) and memory device 3000 (FIG. 30A through FIG. 33D) are labeled with the same labels (same reference numbers).

FIG. 30A and FIG. 30B show memory device 3000 after dielectric pillars 1844 and openings 2065H are formed. The process associated with FIG. 30A and FIG. 30B can be similar to or the same as the process associated with FIG. 10A through FIG. 20B of forming memory device 1000. As shown in FIG. 30A and FIG. 30B, structures 1165 and 1265 can be exposed at respective openings 2065H.

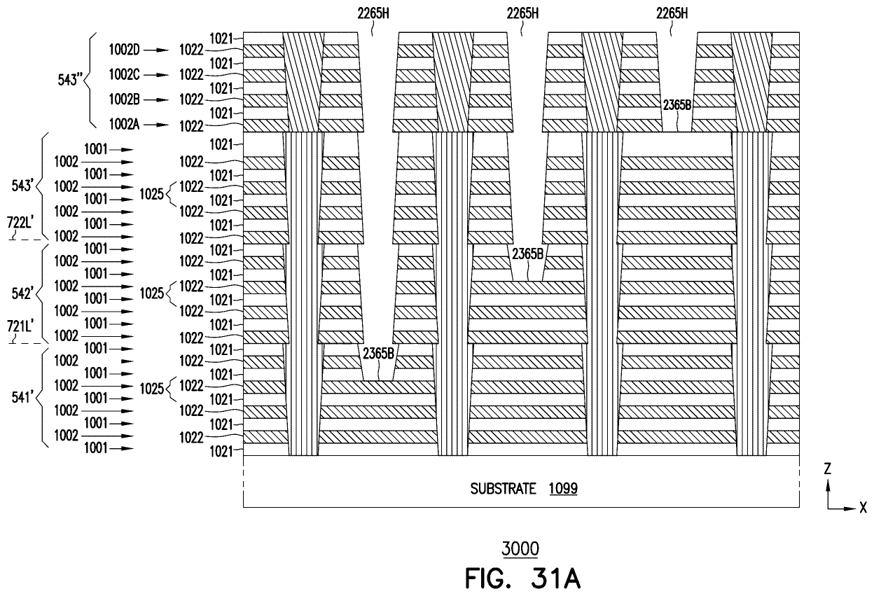

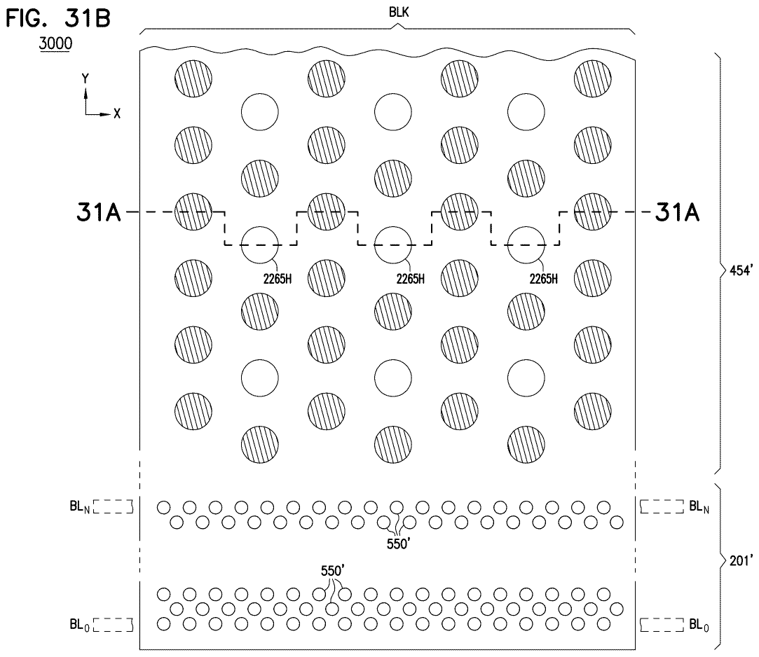

In comparison with the process of enlarging openings 2065H associated with FIG. 21A through FIG. 22B, the processes associated with FIG. 30A through FIG. 33B may skip a process of enlarging openings 2065H of FIG. 30A and FIG. 30B before the processes associated with FIG. 31A and FIG. 31B are performed. However, alternative processes of forming memory device 3000 can include enlarging openings 2065H (e.g., increasing the widths of openings 2065H) of FIG. 30A and FIG. 30B before the processes of removing (e.g., exhuming) structures 1165P and 1265P in FIG. 31A and FIG. 31B.

FIG. 31A and FIG. 31B show memory device 3000 after openings 2265H are formed. Forming openings 2265H can include removing (e.g., exhuming) structures 1165P and 1265P from openings 2065H (FIG. 30A). As shown in FIG. 23A, openings 2465H can have respective bottoms 2465B.

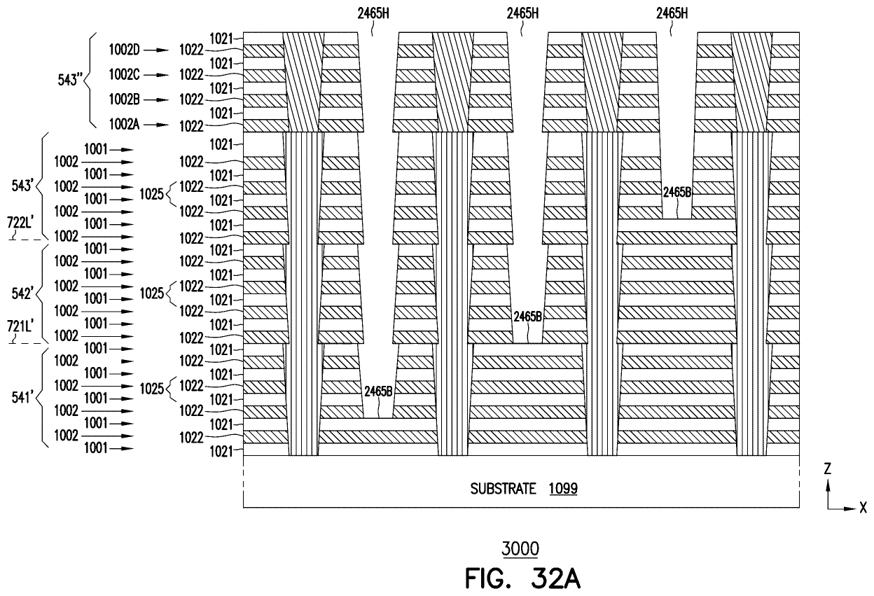

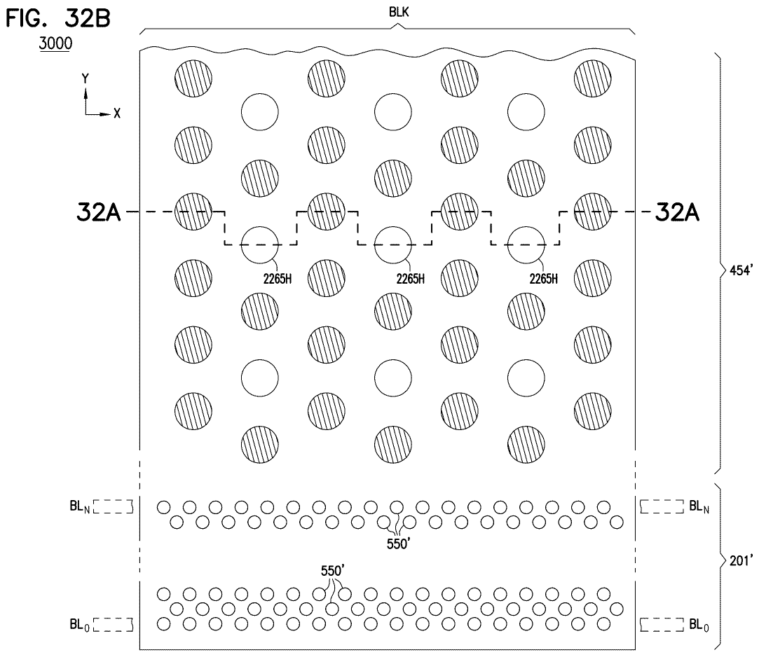

FIG. 32A and FIG. 32B show memory device 3000 after openings 2465H are formed. Forming openings 2465H can include increasing the depths (in the Z-direction) of openings 2265H in FIG. 31A by respective distances from previous depths shown in FIG. 32A. Increasing the depths of openings 2265H (FIG. 21A) can include removing portions of dielectric materials 1021 and 1022 that are directly under bottoms 2365B of openings 2265H (FIG. 31A). As shown in FIG. 32A, openings 2465H can have new respective bottoms 2465B over respective levels of dielectric materials 1021.

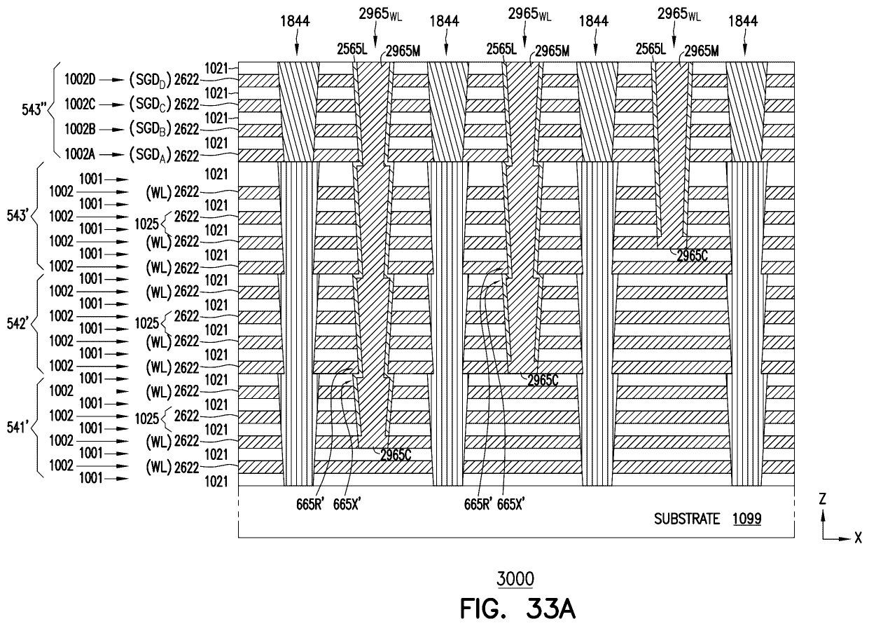

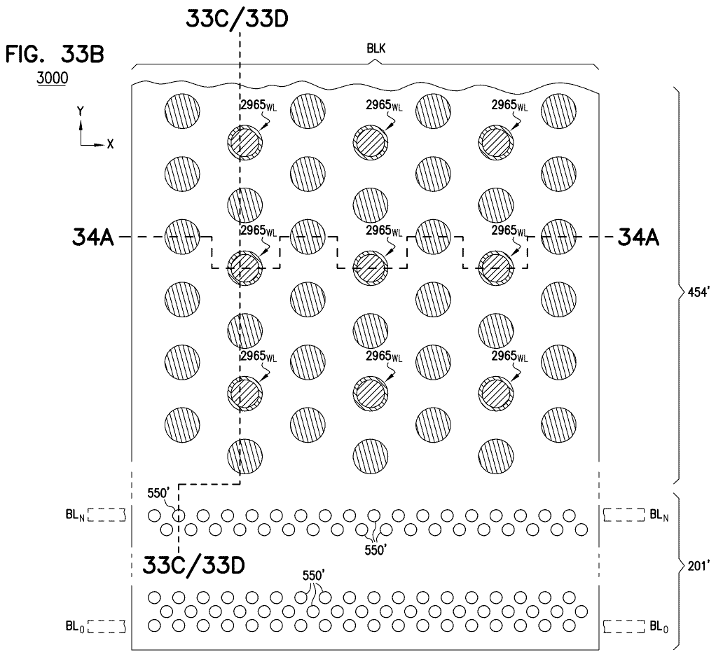

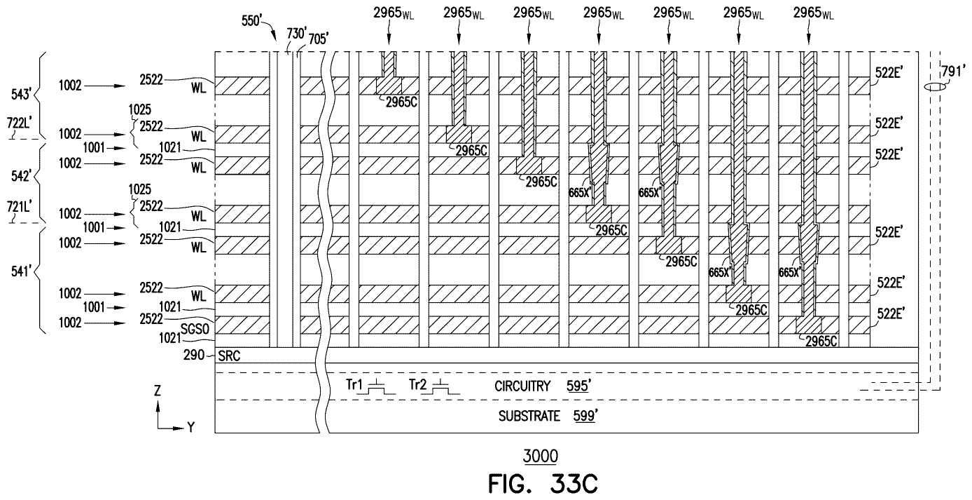

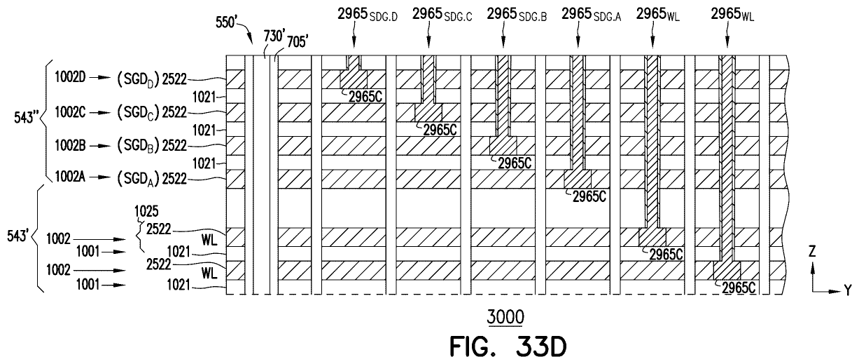

FIG. 33A and FIG. 33B show memory device 3000 after formation of conductive materials 2622 and conductive contacts 2965_{WL}. Forming conductive materials 2622 of memory device 3000 can be similar to (or the same as) forming conductive material 2622 of memory device 1000 of FIG. 26A and FIG. 26B. In FIG. 33A and FIG. 33B, forming conductive contacts 2965_{WL} can include forming liners (dielectric liners) 2565L, conductive pads 2965C, and conductive materials 2965M. The processes of forming conductive contacts 2965_{WL} can be similar to (or the same as) processes of forming conductive contacts 2965_{WL} of memory device 1000 associated with FIG. 24A through FIG. 29B.

FIG. 33A shows a side view of memory device in the X-Z direction. Different side views in the Y-Z direction of memory device 1000 along line 33C/33D are shown in FIG. 33C and FIG. 33D.

FIG. 33C and FIG. 33D show side views of memory device 3000 that include elements similar to or the same as the elements of the side views of memory device 1000 shown in FIG. 29C and FIG. 29D, respectively. Thus, descriptions of the elements of memory device 3000 are omitted.

The processes of forming memory device 3000 described above with reference to FIG. 30A through FIG. 33D can include other processes to form a complete memory device (e.g., memory device 3000). Such processes are omitted from the above description so as not to obscure the subject matter described herein. Moreover, the processes of forming memory device 3000 described above with reference to FIG. 30A through FIG. 33D forms three decks (e.g., decks 541′, 542′, and 543′) of memory device 3000 as an example. However, the processes of forming memory device 3000 described above with reference to FIG. 30A through FIG. 33D can be used to form memory device 3000 that include fewer than three or more than three decks.

The structures and processes of forming the described memory devices (e.g., memory devices 1000 and 3000) can provide improvements and benefits in comparison with the structures and processes of forming some similar conventional memory devices. For example, forming structures 1165P and 1265P (FIG. 12A, FIG. 12B, FIG. 30A, and FIG. 30B) allows formation of openings 2265H (FIG. 23A or FIG. 31A) to remove a portion of dielectric materials 1021 and 1022 from multiple respective decks (e.g., decks 541′, 542, and 543′ in FIG. 23A or FIG. 31A. As shown in FIG. 23A and FIG. 24A (or FIG. 31A and FIG. 32A), since dielectric materials 1021 and 1022 in openings 2265H in FIG. 23A (or FIG. 31A) are already removed, dielectric materials 1021 and 1022 under the bottom (e.g., bottom 2365B in FIG. 23A) of the same opening 2265H from only one deck (e.g., from a single deck like deck 541′, 542′, or 543′ in FIG. 23A or FIG. 31A) may be removed (e.g., in FIG. 24A or FIG. 32A) to access target locations respective control gates in a respective deck. In some conventional processes of forming a conventional memory device similar to the described memory device, dielectric materials (similar to dielectric materials 1021 and 1022 in FIG. 23A) from multiple decks (e.g., upper decks similar to decks 543′ and 542′ in FIG. 23A or FIG. 31A) may need to be removed (e.g., chopped) to access the locations of the control gates in a lower deck (e.g., similar to deck 541′ in FIG. 23A or FIG. 31A) of the conventional memory device. At a certain dimension (e.g., certain aspect ratio) such conventional processes can be susceptible to inaccuracy in accessing target locations (e.g., level 1002 in deck 541′ in FIG. 24A or FIG. 32A) associated with the control gates in a lower deck). Such an inaccuracy may compromise the structure (e.g., increase the chance of electrical short between adjacent control gates) of the conventional memory device. This can lead to reduced reliability and performance of the memory device. Further, such conventional processes may increase cost associated with forming the conventional memory device.

The processes described above, since dielectric materials 1021 and 1022 from one deck (e.g., from a single deck like deck 541′, 542′, or 543′ in FIG. 24A) may be removed in the processes associated with FIG. 24A (or FIG. 32A), the described processes can improve accuracy accessing the levels associated with target locations of respective control gates in the lower deck. This in turn can lead to improved reliability and performance of the described memory device (e.g., memory device 1000 or 3000) formed by the processes described above. Further, the described processes may reduce cost associated with forming the described memory device processes described above. Moreover, as described above, memory device 200 can be formed using processes similar to the processes of forming memory device 1000. Thus, as shown in FIG. 7, FIG. 8A, FIG. 8B, and FIG. 8C, the structure of memory device 200 at conductive contacts 665_{WL} in decks 541, 542, and 543 can be similar to the structure of memory device 1000 or 3000. Therefore, memory device 200 can also include improvements and benefits similar to those of memory devices 1000 and 3000.

The illustrations of apparatuses (e.g., memory devices 100, 200, 900, 1000, and 3000) and methods (e.g., method of forming memory devices 1000 and 3000) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 900, 1000, and 3000) or a system (e.g., a computer, a cellular phone, or other electronic systems) that includes a device such as any of memory devices 100, 200, 900, 1000, and 3000.

Any of the components described above with reference to FIG. 1 through FIG. 33D can be implemented in a number of ways, including simulation via software. Thus, apparatuses, e.g., memory devices 100, 200, 900, 1000, and 3000 or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 900, 1000, and 3000 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 33D include apparatuses and methods of forming the apparatuses. One of the apparatuses includes: levels of dielectric materials interleaved with the levels of conductive materials, the levels of conductive materials including a first level and a second level; a memory cell string including a pillar extending through the levels of conductive materials and the levels of dielectric materials; and a conductive contact extending in a direction from the first level to the second level, the conductive contact contacting the second level of the levels of conductive materials. The conductive contact includes first region having a first width, a second region having a second width, and a third region having a third width. The second region is between the first region and the third region. The second width is greater than each of the first width and the third width. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
levels of conductive materials;
levels of dielectric materials interleaved with the levels of conductive materials, the levels of conductive materials including a first level and a second level;
a memory cell string including a pillar extending through the levels of conductive materials and the levels of dielectric materials; and
a conductive contact extending in a direction from the first level of the levels of conductive materials to the second level of the levels of conductive materials, the conductive contact contacting the second level of the levels of conductive materials, wherein:
the conductive contact includes first region having a first width, a second region having a second width, and a third region having a third width; and
the second region is between the first region and the third region, and the second width is greater than each of the first width and the third width.

2. The apparatus of claim 1, further comprising an additional conductive contact contacting the first level of the levels of conductive materials, wherein:
the additional conductive contact includes first additional region having a first additional width, a second additional region having a second additional width, and a third additional region having a third additional width; and
the second additional region is between the first additional region and the third additional region, and the second additional width is greater than each of the first additional width and the third additional width.

3. The apparatus of claim 2, wherein the additional conductive contact is closer to the pillar than the conductive contact, and wherein:
the first level of the levels of conductive materials includes a first edge;
the second level of the levels of conductive materials includes a second edge;
the conductive contact is between the pillar of the memory cell string and the first edge; and
the conductive contact is between the pillar of the memory cell string and the second edge.

4. The apparatus of claim 2, wherein the additional conductive contact includes a first length, the conductive contact includes a second length unequal to the first length.

5. The apparatus of claim 2, wherein apparatus comprises a memory device, wherein:
a first portion of the levels of dielectric materials and a first portion of the levels of conductive materials are included in a first deck of the memory device;
a second portion of the levels of dielectric materials and a second portion of the levels of conductive materials are included in a second deck of the memory device; and
the first level of the levels of conductive materials is included in the first deck, and the second level of the levels of conductive materials is included in the first deck.

6. The apparatus of claim 5, wherein the first level of the levels of conductive materials is adjacent the second level of the levels of conductive materials.

7. The apparatus of claim 1, wherein the first level of the levels of conductive materials and the second level of the levels of conductive materials have a same length.

8. The apparatus of claim 1, further comprising a first dielectric pillar adjacent the conductive contact, a second dielectric pillar adjacent the conductive contact, wherein the first dielectric pillar and the second dielectric pillar have a same length.

9. An apparatus comprising:
memory cells located on tiers of the apparatus;
control gates associated the memory cells, the control gates including a first control gate located on a first tier of the tiers, and a second control gate located on a second tier of the tiers;
a first conductive contact contacting the first control gate, the first conductive contact having a first length in a first direction from the first tier to the second tier; and
a second conductive contact contacting the second control gate, the second conductive contact having a second length in the first direction, wherein:
the second conductive contact includes a first portion and a second portion, the second portion is between the first portion and the second control gate, the first portion including a first region having a first width in a second direction, the second portion including a second region having a second width in the second direction, wherein the second width is greater than the first width.

10. The apparatus of claim 9, wherein:
the first portion of the second conductive contact includes a third region having a third width; and
the second portion of the second conductive contact includes a fourth region having a fourth width, wherein the third width is greater than the fourth width.

11. The apparatus of claim 9, wherein:
the first conductive contact includes a first additional portion and a second additional portion, the second additional portion is between the first additional portion and the first control gate, the first additional portion including a first additional region having a first additional width in the second direction, the second additional portion including a second additional region having a second additional width in the second direction, wherein the second additional width is greater than the first additional width.

12. The apparatus of claim 11, wherein the first control gate is adjacent the second control gate.

13. The apparatus of claim 9, wherein the first conductive contact includes a first conductive pad contacting the first control gate, and the second conductive contact includes a second conductive pad contacting the second control gate.

14. The apparatus of claim 9, wherein the second length of the second conductive contact is greater than the first length of the first conductive contact.

15. The apparatus of claim 14, wherein:
the first control gate includes a first edge;
the second control gate includes a second edge;
the second conductive contact is between a memory pillar associated with the memory cells and the first edge; and
the second conductive contact is between the memory pillar and the second edge.

16. A method comprising:
forming levels of first materials interleaved with levels of second materials;
forming a structure in a portion of the levels of first materials and the levels of second materials;
forming, over the structure and over the levels of first materials and the levels of second materials, additional levels of first materials interleaved with additional levels of second materials;
forming an opening over the structure to expose the structure at the opening;
removing the structure;
removing a portion of the levels of first materials and a portion of the levels of second materials at the opening;
replacing the levels of second materials with respective levels of conductive materials; and
forming a conductive contact at a location of the opening, such that the conductive contact contacts one of the levels of conductive materials.

17. The method of claim 16, wherein forming the structure includes:
removing portion of the levels of first materials and the levels of second materials to form an initial opening; and
forming a material in the initial opening.

18. The method of claim 17, wherein forming the structure includes:
forming a liner in the initial opening before the material is formed in the initial opening; and
forming the material in the initial opening after the liner is formed.

19. The method of claim 16, further comprising:
enlarging a width of the opening before removing the structure.

20. The method of claim 19, wherein enlarging the width of the opening includes:
removing a portion of the additional levels of first materials and a portion of the additional levels of second materials at the location of the opening.
